(19) United States
(12) Patent Application Publication
(10) Pub. No.: US 2021/0382392 A1
(43) Pub. Date: Dec. 9, 2021

(54) HARD-MASK FORMING COMPOSITION AND METHOD FOR MANUFACTURING ELECTRONIC COMPONENT

(71) Applicant: TOKYO OHKA KOGYO CO., LTD., Kawasaki-shi (JP)

(72) Inventors: Junichi TSUCHIYA, Kawasaki-shi (JP); Keiichi IBATA, Kawasaki-shi (JP)

(21) Appl. No.: 17/303,374

(22) Filed: May 27, 2021

(30) Foreign Application Priority Data
Jun. 5, 2020 (JP) 2020-098414

(51) Int. Cl. G03F 7/11; G03F 7/004

(52) U.S. Cl. CPC G03F 7/11; G03F 7/0045

(57) ABSTRACT

A hard-mask forming composition including a resin containing a structural unit represented by General Formula (u1-1) or a structural unit represented by General Formula (u1-2) and a compound represented by General Formula (c-1), in which R¹¹ and R¹² are aromatic hydrocarbon groups which may have a substituent, Y is an organic group, R⁰¹ is a hydrocarbon group, R⁰² is an alkyl group, n1 is an integer of 0 to 3, n2 is an integer of 1 to 4, n3 is an integer of 1 to 3, n4 is an integer of 3 or more, and the number of —CH₂OR⁰² is 6 or more

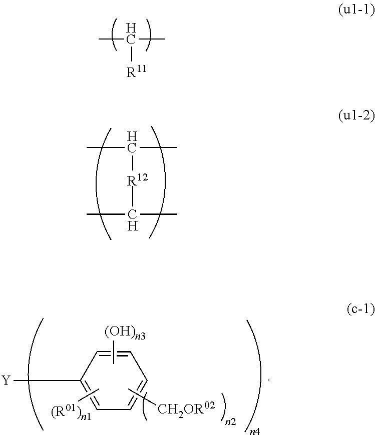

### BACKGROUND OF THE INVENTION

### Field of the Invention

The present invention relates to a hard-mask forming composition and a method for manufacturing an electronic component.

Priority is claimed on Japanese Patent Application No. 2020-098414, filed on Jun. 5, 2020, the content of which is incorporated herein by reference.

### Description of Related Art

Generally, in semiconductor manufacturing, a laminate in which a resist film is formed on a substrate, such as a silicon wafer, is subjected to processing including dry etching, for example, a treatment in which a resist film is selectively exposed to form a resist pattern on the resist film, and dry etching is performed using thereof as a mask, thereby forming a pattern on the substrate.

As a pattern forming method using a resist film, a three-layer resist method is known (for example, see Japanese Unexamined Patent Application First Publication No. 2001-051422). The three-layer resist method is that, first, an organic hard mask layer is formed using an organic material on a support, an inorganic hard mask layer is formed thereon using an inorganic material, and then a resist film is further formed on the inorganic hard mask layer. Subsequently, a resist pattern is formed by typical lithography, the inorganic hard mask layer is etched with the resist pattern as a mask to form an inorganic hard mask pattern, and then the organic hard mask layer is etched with the inorganic hard mask layer pattern as a mask to form an organic hard mask pattern. Then, the organic hard mask pattern is etched as a mask to process the support.

Additionally, a two-layer resist method with fewer steps than the three-layer resist method has also been proposed (for example, see Japanese Unexamined Patent Application First Publication Nos. S61-239243 and S62-025744). The two-layer resist method is that the organic hard mask layer is provided on the support in the same manner as in the three-layer resist method, and then the resist film is provided on the organic hard mask layer. Subsequently, the resist pattern is formed by typical lithography, and the organic hard mask layer is etched with the resist pattern as a mask to form the organic hard mask pattern. Then, the organic hard mask pattern is etched as a mask to process the support.

As a method of forming the organic hard mask layer, a chemical vapor deposition method (hereinafter, sometimes referred to as a CVD method) is known in the related art. The CVD method uses amorphous carbon as a hard-mask forming material and has problems including slow throughput and expensive equipment investment.

Therefore, film formation by spin-on-coating has been introduced in recent years (for example, see Japanese Unexamined Patent Application First Publication No. 2015-091775), for which organic hard-mask forming materials applicable to the method has been proposed. The spin-on-coating has advantageous effects of high throughput and usability of the existing spin coater as compared with the CVD method.

As the organic hard-mask forming material, for example, a composition containing a specific resin having a polycyclic aromatic group is used in order to obtain high etching resistance.

### CITATION LIST

### Patent Literature

[Patent Literature 1] Japanese Unexamined Patent Application First Publication No. 2001-51422

[Patent Literature 2] Japanese Unexamined Patent Application First Publication No. S61-239243

[Patent Literature 3] Japanese Unexamined Patent Application First Publication No. S62-25744

[Patent Literature 4] Japanese Unexamined Patent Application Publication No. 2015-91775

### SUMMARY OF THE INVENTION

A hard mask layer formed by using a hard-mask forming material in the related art having high etching resistance is hard but brittle and tends to have low crack resistance, and it is difficult to achieve both etching resistance and crack resistance at the same time. In addition, the hard-mask forming material in the related art also has a problem that outgas is generated when the hard mask layer is formed on the support.

The present invention is made in view of the problems described above, and an object of the present invention is to provide a hard-mask forming composition excellent in etching resistance, crack resistance, and low outgassing property and a method for manufacturing an electronic component using the hard-mask forming composition.

The present invention adopts the following composition in order to solve the problems.

That is, a first aspect of the present invention provides a hard-mask forming composition, which forms a hard mask used in lithography, comprising: a resin (P1) containing a structural unit (u11) represented by General Formula (u1-1) or a structural unit (u12) represented by General Formula (u1-2) and a structural unit (u2) having an aromatic ring or a polar group; and a compound (C1) represented by General Formula (c-1).

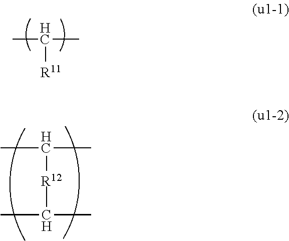

In Formula (u1-1), R¹¹ is an aromatic hydrocarbon group which may have a substituent.

In Formula (u1-2), R¹² is an aromatic hydrocarbon group which may have a substituent.

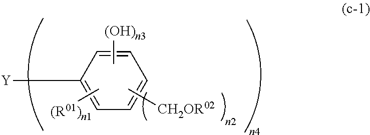

[In the formula, Y is an organic group. R⁰¹ is a hydrocarbon group having 1 to 40 carbon atoms. R⁰² is an alkyl group having 1 to 10 carbon atoms which may have an alkoxy group having 1 to 10 carbon atoms. n1 is an integer of 0 to 3, n2 is an integer of 1 to 4, n3 is an integer of 1 to 3, and n1 to n3 satisfy 2≤n1+n2+n3≤5. n4 is an integer of 3 or more, and a plurality of R⁰¹'s, R⁰²'s, n1's, n2's, and n3's may be the same as or different from each other, respectively. Here, the number of —CH₂OR⁰² in the formula is 6 or more as a whole of the compound (C1).]

A second aspect of the present invention is a method for manufacturing an electronic component including: forming a hard mask layer (m1) on a support using the hard-mask forming composition according to the first aspect; and processing the support using the hard mask layer (m1) as a mask.

A third aspect of the present invention provides a method for manufacturing an electronic component, including: forming a hard mask layer (m1) on a support using the hard-mask forming composition according to the first aspect; forming a hard mask layer (m2) made of an inorganic material on the hard mask layer (m1); forming a resist film on the hard mask layer (m2); exposing the resist film and developing the exposed resist film to form a resist pattern on the hard mask layer (m2); etching the hard mask layer (m2) using the resist pattern as a mask to form an inorganic pattern; etching the hard mask layer (m1) using the inorganic pattern as a mask to form a resin pattern; and processing the support using the resin pattern as a mask.

A fourth aspect of the present invention provides a method for manufacturing an electronic component, including: forming a hard mask layer (m1) on a support using the hard-mask forming composition according to the first aspect; forming an inorganic pattern made of an inorganic material on the hard mask layer (m1); etching the hard mask layer (m1) using the inorganic pattern as a mask to form a resin pattern; and processing the support using the resin pattern as a mask.

According to the present invention, it is possible to provide a hard-mask forming composition excellent in etching resistance, crack resistance, and low outgassing property, and a method for manufacturing an electronic component using the hard-mask forming composition.

### BRIEF DESCRIPTION OF THE DRAWINGS

FIG. 1 is a cross-sectional view showing an exemplified support used in a method for manufacturing an electronic component according to an embodiment of the present invention.

FIG. 2 is a view illustrating an exemplified process of forming a hard mask layer (m1) in the method for manufacturing an electronic component according to the embodiment of the present invention.

FIG. 3 is a view illustrating an exemplified process of forming a hard mask layer (m2) in the method for manufacturing an electronic component according to the embodiment of the present invention.

FIG. 4 is a view illustrating an exemplified process of forming a resist film in the method for manufacturing an electronic component according to the embodiment of the present invention.

FIG. 5 is a view illustrating an exemplified process of forming a resist pattern in the method for manufacturing an electronic component according to the embodiment of the present invention.

FIG. 6 is a view illustrating an exemplified process of forming an inorganic pattern in the method for manufacturing an electronic component according to the embodiment of the present invention.

FIG. 7 is a view illustrating an exemplified process of forming a resin pattern in the method for manufacturing an electronic component according to the embodiment of the present invention.

FIG. 8 is a view illustrating an exemplified process of processing a support in the method for manufacturing an electronic component according to the embodiment of the present invention.

### DETAILED DESCRIPTION OF THE INVENTION

In the specification and claims of the present invention, the term “aliphatic” is a relative concept to aromatic, and is defined to mean a group, a compound, or the like, which has no aromaticity.

The term “alkyl group” is intended to encompass linear, branched and cyclic monovalent saturated hydrocarbon groups, unless otherwise specified. The same definition applies to an alkyl group in an alkoxy group.

The term “alkylene group” is intended to encompass linear, branched, and cyclic divalent saturated hydrocarbon groups, unless otherwise specified.

The term “halogenated alkyl group” refers to a group in which a part or all of the hydrogen atoms of the alkyl group are substituted with halogen atoms, and examples of the halogen atom include a fluorine atom, a chlorine atom, a bromine atom, and an iodine atom.

The term “fluorinated alkyl group” or “fluorinated alkylene group” refers to a group in which a part or all of hydrogen atoms of an alkyl group or an alkylene group are substituted with fluorine atoms.

The term “structural unit” refers to a monomer unit (monomer unit) constituting a polymer compound (resin, polymer, or copolymer).

The expression “may have a substituent” includes both cases where a hydrogen atom (—H) is substituted with a monovalent group, and where a methylene group (—CH₂—) is substituted with a divalent group.

The term “expose” is a concept that includes general radiation irradiations.

In the specification and claims of the present invention, some structures represented by a chemical formula have an asymmetric carbon, and there may be enantiomers or diastereomers. In this case, those isomers are collectively represented by one formula. The isomers may be used alone, or may be used as a mixture.

(Hard-mask Forming Composition)

The hard-mask forming composition according to the first aspect of the present invention is a composition for forming a hard mask used in lithography. The hard-mask forming composition of the present embodiment includes a resin (P1) having a structural unit (u11) represented by General Formula (u1-1) or a structural unit (u12) represented by General Formula (u1-2) and a structural unit (u2) having an aromatic ring and a polar group, and a compound (C1) represented by General Formula (c-1).

<Resin (P1)>

The resin (P1) has a structural unit (u11) represented by General Formula (u1-1) or a structural unit (u12) represented by General Formula (u1-2) and a structural unit (u2) having an aromatic ring and a polar group.

Structural Unit (u11)

The structural unit (u11) is a structural unit represented by General Formula (u1-1).

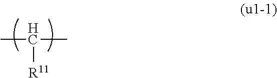

[In Formula (u1-1), R¹¹ is an aromatic hydrocarbon group which may have a substituent.]

In Formula (u1-1), R¹¹ is an aromatic hydrocarbon group which may have a substituent. Examples of the substituent include a carbonyl group, an alkoxy group, a halogen atom, an alkyl group, an alkenyl group, an alkynyl group, and the like.

The aromatic hydrocarbon group for R¹¹ has preferably 6 to 30 carbon atoms, and more preferably 6 to 25 carbon atoms. The aromatic hydrocarbon group for R¹¹ is a hydrocarbon group which has at least one aromatic ring. The aromatic ring is not particularly limited as long as it is a cyclic conjugated system having 4n+2 π electrons, and may be monocyclic or polycyclic. The aromatic ring has preferably 5 to 20 carbon atoms, more preferably 5 to 18 carbon atoms, and still more preferably 6 to 16 carbon atoms.

Specific examples of the aromatic ring include an aromatic hydrocarbon ring such as benzene, naphthalene, anthracene, phenanthrene, pyrene, or the like; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyrrolidine ring, a pyridine ring, a thiophene ring, and the like.

Specific examples of the aromatic hydrocarbon group for R¹¹ include a group (an aryl group or a heteroaryl group) obtained by removing one hydrogen atom from the aromatic hydrocarbon ring or the aromatic heterocyclic ring; a group obtained by removing one hydrogen atom from an aromatic compound (for example, biphenyl, fluorene, and the like) containing two or more aromatic rings; a group (for example, an arylalkyl group such as benzyl group, phenethyl group, 1-naphthylmethyl group, 2-naphthylmethyl group, 1-naphthylethyl group, 2-naphthylethyl group, and the like) in which one of hydrogen atoms of the aromatic hydrocarbon ring or the aromatic heterocyclic ring is substituted with an alkylene group; and the like. An alkylene group to be bonded to the aromatic hydrocarbon ring or the aromatic heterocyclic ring has preferably 1 to 4 carbon atoms, more preferably 1 to 2 carbon atoms, and particularly preferably 1 carbon atom.

Specific examples of R¹¹ in Formula (u1-1) are shown below. The symbol * represents a bonding site.

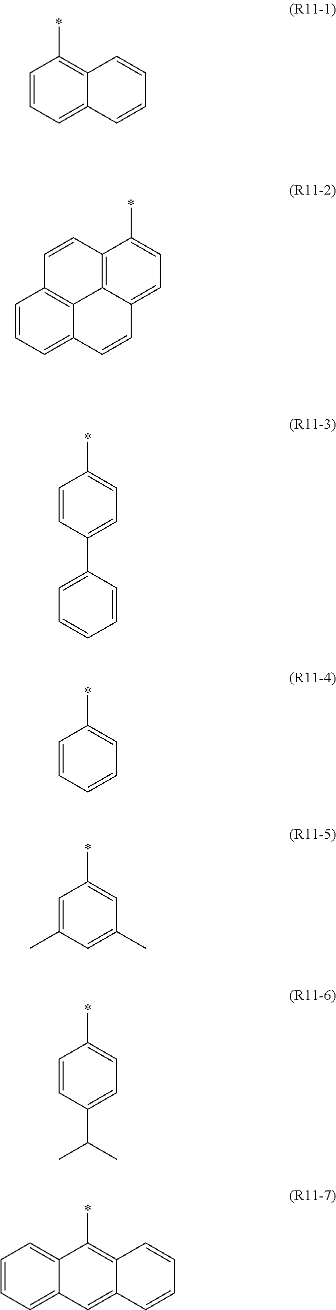

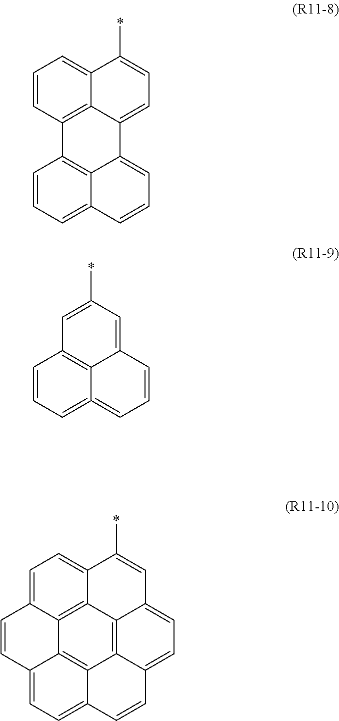

Among these, R¹¹ in Formula (u1-1) is preferably a naphthyl group, a pyrenyl group, and a biphenyl group.

Specifically, as the structural unit (u11) in the present embodiment, structural units shown below are preferable.

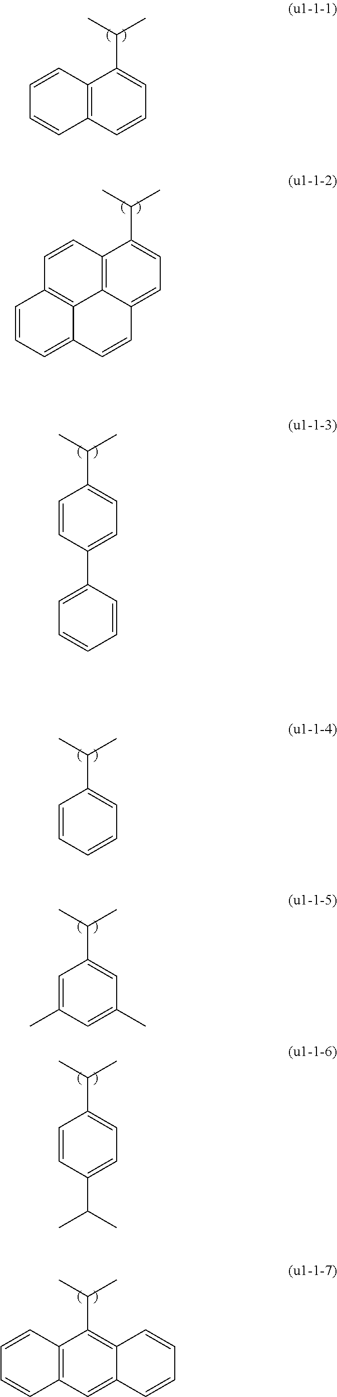

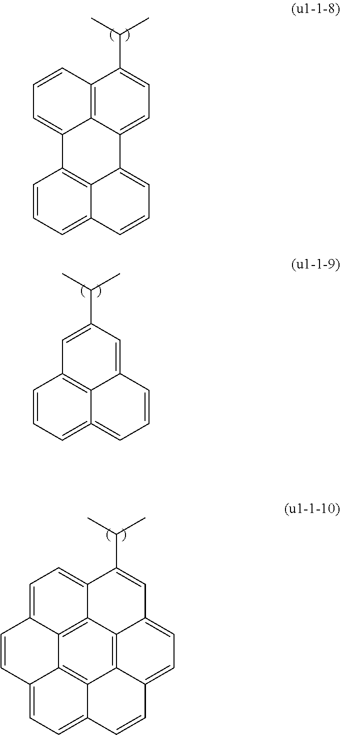

Among these, as the structural unit (u11) in the present embodiment, the structural unit represented by any of Formulae (u1-1-1) to (u1-1-3) is preferable, and the structural unit represented by Formula (u1-1-1) or (u1-1-2) is more preferable.

The structural unit (u11) of the resin (P1) may be one, or may be two or more.

Structural Unit (u12)

The structural unit (u12) is a structural unit represented by General Formula (u1-2).

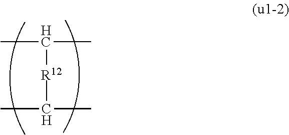

[In Formula (u1-2), R¹² is an aromatic hydrocarbon group which may have a substituent.]

In Formula (u1-2), R¹² is an aromatic hydrocarbon group which may have a substituent, and examples thereof include the same ones as R¹¹ in Formula (u1-1) stated above.

Specific examples of the structural unit (u12) are shown below.

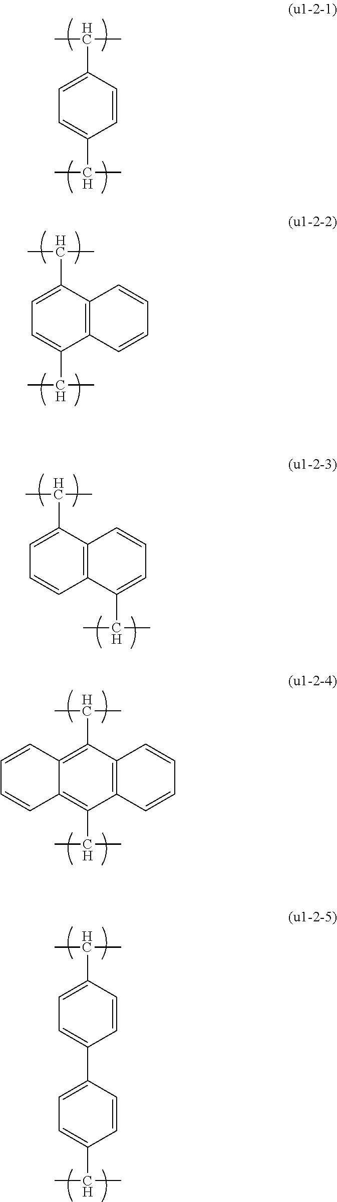

The structural unit (u12) of the resin (P1) may be one, or may be two or more.

The resin (P1) preferably has a structural unit (u11) among the structural unit (u11) and the structural unit (u12).

Structural Unit (u2)

The structural unit (u2) is a structural unit having an aromatic ring and a polar group.

The aromatic ring contained in the structural unit (u2) is not particularly limited as long as it is a cyclic conjugated system having 4n+2 π electrons, and may be monocyclic or polycyclic. The aromatic ring has preferably 5 to 30 carbon atoms, more preferably 5 to 20 carbon atoms, and still more preferably 6 to 16 carbon atoms.

Specific examples of the aromatic ring include an aromatic hydrocarbon ring such as benzene, naphthalene, anthracene, and phenanthrene; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyridine ring, a thiophene ring, and the like. The aromatic heterocyclic ring (for example, a pyridine ring, a thiophene ring) has an aromatic ring and a polar group.

The aromatic ring contained in the structural unit (u2) may be one, or may be two or more.

Examples of the polar group contained in the structural unit (u2) include a monovalent polar group such as a hydroxy group, a carboxy group, an amino group, a sulfo group, an alkoxy group, and an epoxy group; a divalent polar group such as a group represented by —O—, —C(═O)—O—, —C(═O)—, —O—C(═O)—O—, —C(═O)—NH—, —NH—, —NH—C(═NH)—(H may be substituted with a substituent such as alkyl group and acyl group), —S—, —S(═O)₂—, —S(═O)₂—O—, -General Formula-Y²¹—O—Y22-, —Y²¹—O—, —Y²¹—C(═O)—O—, —C(═O)—O—Y²¹—, [Y²¹—C(═O)—O]_{m″}—Y²²—, —Y²¹ —O—C(═O)—Y²²— or —y²¹—S(═O)2-O—Y²²— [in Formula, Y²¹ and Y²² are each independently a divalent hydrocarbon group which may have a substituent, O is an oxygen atom, and m″ is an integer of 0 to 3]; and the like. In addition, the polar group contained in the structural unit (u2) may be obtained by forming a cyclic structure formed by the divalent polar group and a hydrocarbon group.

The polar group contained in the structural unit (u2) may be one, or may be two or more.

Specific examples of the structural unit (u21) include a structural unit derived from a phenol compound. The phenol compound is preferably a compound that can be condensed with an aldehyde to form a novolac resin or a resol resin. Examples of such a phenol compound include phenol; cresols such as m-cresol, p-cresol, o-cresol, and the like; xylenols such as 2,3-xylenol, 2,5-xylenol, 3,5-xylenol, 3,4-xylenol, and the like; alkylphenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-methylphenol, 2-tert-butyl-5-methylphenol, and the like; alkoxyphenols such as p-methoxyphenol, m-methoxyphenol, p-ethoxyphenol, m-ethoxyphenol, p-propoxyphenol, m-propoxyphenol, and the like; isopropenylphenols such as o-isopropenylphenol, p-isopropenylphenol, 2-methyl-4-isopropenylphenol, 2-ethyl-4-isopropenylphenol, and the like; arylphenols such as phenyl phenol and the like; polyhydroxyphenols such as 4,4′-dihydroxybiphenyl, bisphenol A, resorcinol, hydroquinone, pyrogallol, 9,9-bis (4-hydroxy-3,5-dimethylphenyl) fluorene, 9,9-bis (4-hydroxy-3-methylphenyl) fluorene, 1,1-bis (4-hydroxy-3-methylphenyl) cyclohexane, and the like; and the like.

As the structural unit (u2), a structural unit (u21) represented by General Formula (u2-1), a structural unit (u22) represented by General Formula (u2-2), or a structural unit (u23) represented by General Formula (u2-3) is preferable.

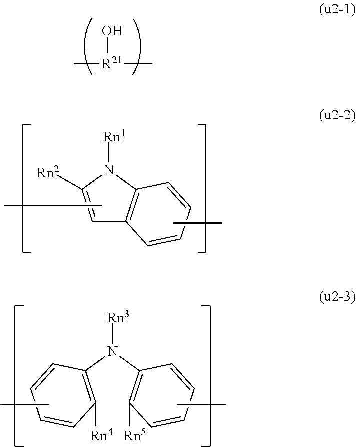

[In Formula (u2-1), R²¹ is an aromatic hydrocarbon group which may have a substituent. In Formula (u2-2), Rn¹ and Rn² are each independently a hydrogen atom or a hydrocarbon group. In Formula (u2-3), Rn³ to Rn⁵ are each independently a hydrogen atom or a hydrocarbon group. Rn⁴ and Rn⁵ may be bonded to each other to form a condensed ring with the nitrogen atom in Formula.]

In Formula (u2-1), the aromatic hydrocarbon group for R²¹ is a hydrocarbon group having at least one aromatic ring. The aromatic ring is the same as the content described with respect to the aromatic ring contained in the structural unit (u2). Examples of the substituent include a carbonyl group, an alkoxy group, a halogen atom, an alkyl group, an alkenyl group, an alkynyl group, and the like. The alkyl group, the alkenyl group, and the alkynyl group in the substituent preferably have 1 to 5 carbon atoms, and more preferably have 1 to 3 carbon atoms.

In Formula (u2-1), the aromatic hydrocarbon group for R²¹ is preferably a group having no substituent from a viewpoint of improving etching resistance.

Specific examples of the structural unit (u21) are shown below.

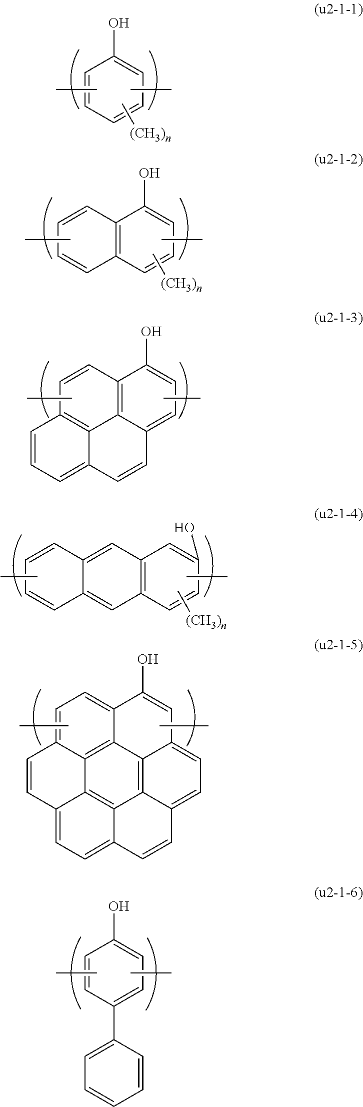

[In Formulae (u2-1-1), (u2-1-2), and (u2-1-4), n is an integer of 0 to 3.]

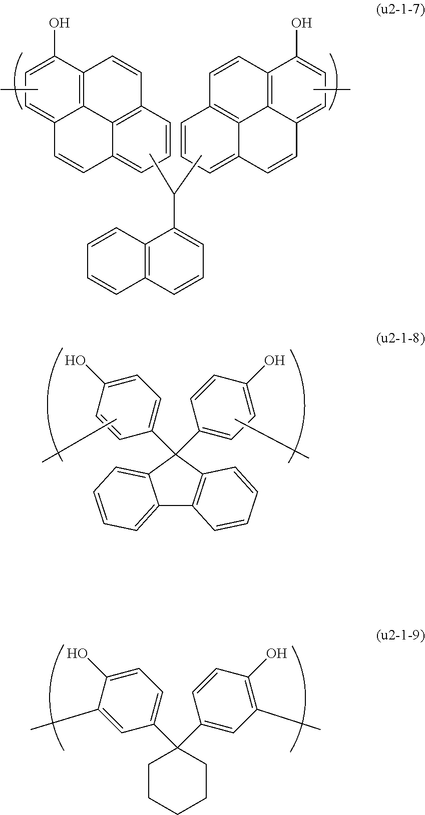

Among these, the structural unit (u21) is preferably a structural unit represented by any of Formulae (u21-2) to (u21-4), and is more preferably a structural unit represented by Formula (u21-2) or (u21-3).

The structural unit (u21) of the resin (P1) may be one, or may be two or more.

Structural Unit (u22)

The structural unit (u22) is a structural unit represented by General Formula (u2-2).

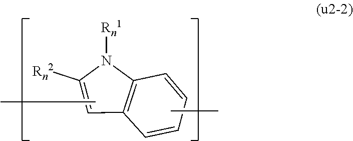

[In Formula (u2-2), Rn¹ and Rn² are each independently a hydrogen atom or a hydrocarbon group.]

Examples of the hydrocarbon group for Rn¹ and Rn² include a chain hydrocarbon group or a cyclic hydrocarbon group, or a hydrocarbon group combining a chain and a ring.

Examples of the chain hydrocarbon group include a linear alkyl group and a branched alkyl group.

As the linear alkyl group, a methyl group, an ethyl group, a propyl group, a butyl group, and a pentyl group are preferable, and a methyl group is preferable.

Examples of the branched alkyl group include 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group, and 4-methylpentyl group.

The cyclic hydrocarbon group may be an alicyclic hydrocarbon group, or may be an aromatic hydrocarbon group.

The alicyclic hydrocarbon group may be either monocyclic or polycyclic.

Examples of the monocyclic alicyclic hydrocarbon group include cycloalkyl groups such as a cyclopropyl group, a cyclobutyl group, a cyclopentyl group, a cyclohexyl group, a methylcyclohexyl group, a dimethylcyclohexyl group, a cycloheptyl group, a cyclooctyl group, a cyclononyl group, and a cyclodecyl group.

Examples of the polycyclic alicyclic hydrocarbon group include a decahydronaphthyl group, an adamantyl group, a 2-alkyladamantane-2-yl group, a 1-(adamantane-1-yl) alkane-1-yl group, a norbornyl group, a methylnorbornyl group, an isobornyl group, and the like.

Examples of the aromatic hydrocarbon group include a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, a 2-methyl-6-ethylphenyl group, and the like.

Among these, Rn¹ in Formula (u2-2) is preferably hydrogen atom or a linear alkyl group having 1 to 5 carbon atoms, and more preferably a hydrogen atom.

Among these, Rn² in Formula (u2-2) is preferably a hydrogen atom or an aromatic hydrocarbon group, more preferably an aromatic hydrocarbon group, and still more preferably a phenyl group.

The structural unit (u22) of the resin (P1) may be one, or may be two or more.

Specific examples of the structural unit (u22) are shown below.

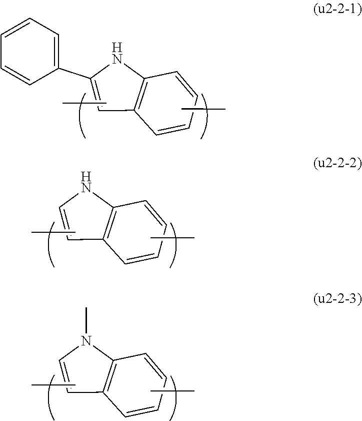

Structural Unit (u23)

The structural unit (u23) is a structural unit represented by General Formula (u2-3).

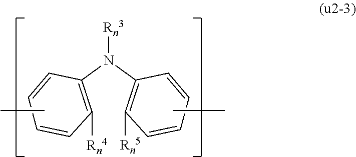

[In Formula (u2-3), Rn³ to Rn⁵ are each independently a hydrogen atom or a hydrocarbon group. Rn⁴ and Rn⁵ may be bonded to each other to form a condensed ring with the nitrogen atom in Formula.]

In Formula (u2-3), Rn³ to Rn⁵ are each independently a hydrogen atom or a hydrocarbon group. Examples of the hydrocarbon group include those similar to Rn¹ and Rn² in Formula (u2-3).

In Formula (u2-3), Rn⁴ and Rn⁵ may be bonded to each other to form a condensed ring together with a nitrogen atom in Formula. The condensed ring is preferably a carbazole ring.

Among these, Rn³ in Formula (u2-3) is preferably a hydrogen atom or an aromatic hydrocarbon group, and more preferably a hydrogen atom or a naphthyl group.

Among these, Rn⁴ and Rn⁵ in Formula (u2-3) are preferably hydrogen atoms or form a carbazole ring together with the nitrogen atom in Formula, and more preferably form a carbazole ring together with the nitrogen atom in Formula.

The structural unit (u23) of the resin (P1) may be one, or may be two or more.

Specific examples of the structural unit (u23) are shown below.

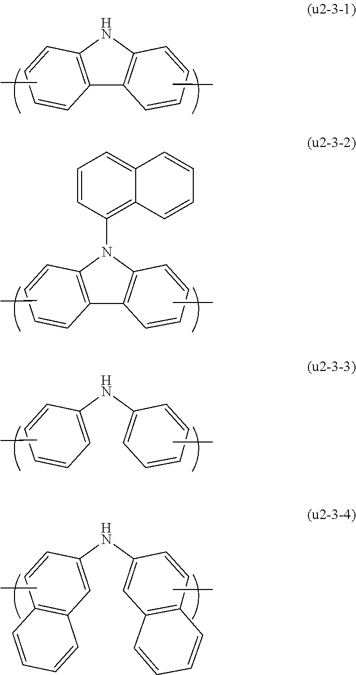

Examples of the resin (P1) includes a resin having at least one structural unit selected from the group consisting of the structural unit (u11), the structural unit (u21), the structural unit (u22), and the structural unit (u23); and a resin having at least one structural unit selected from the group consisting of the structural unit (u12), the structural unit (u21), the structural unit (u22), and the structural unit (u23).

Among these, the resin (P1) is preferably a copolymer of a resin having at least one structural unit selected from the group consisting of the structural unit (u11), the structural unit (u21), the structural unit (u22), and the structural unit (u23), that is, a monomer derived from the structural unit (u11), and a monomer derived from at least one structural unit selected from the group consisting of the structural unit (u21), the structural unit (u22), and the structural unit (u23).

A weight average molecular weight (Mw) (based on polystyrene conversion by gel permeation chromatography (GPC)) of the resin (P1) is not particularly limited, and is preferably 1,000 to 500,000, more preferably 1,000 to 20,000, and still more preferably 1,000 to 10,000. In a case where Mw of the resin (P1) is within the preferable range, etching resistance and heat resistance are preferable.

The dispersity (Mw/Mn) of the resin (P1) is not particularly limited, and is preferably 1.0 to 4.0, and more preferably 1.0 to 3.0. Mn represents a number average molecular weight.

Specific examples of the resin (P1) are shown below.

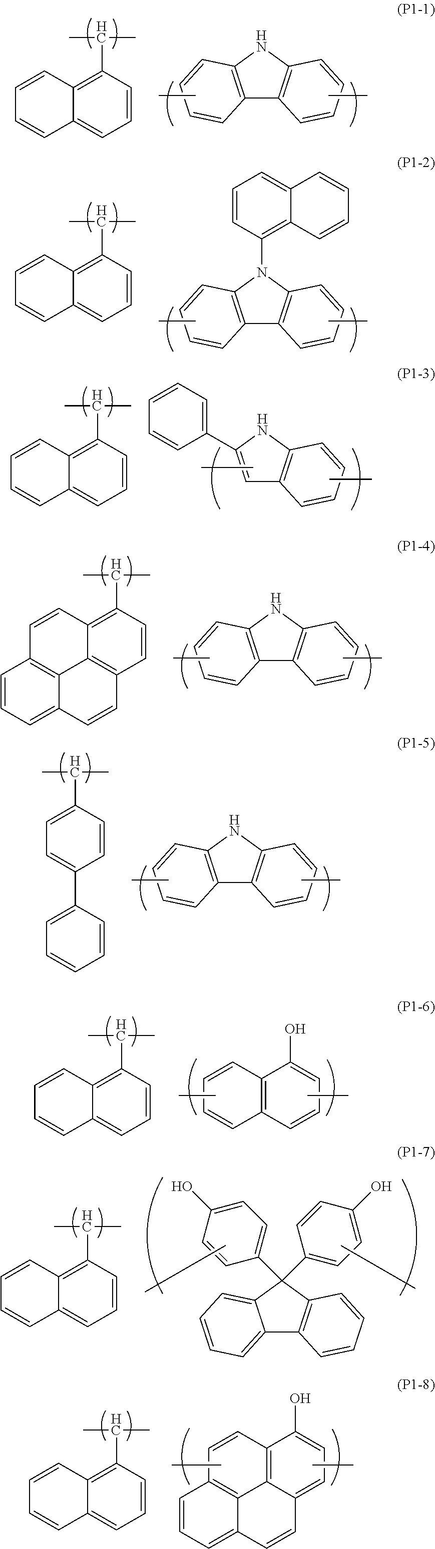

The hard-mask forming composition of the present embodiment may contains a resin other than the resin (P1) stated above, but a proportion of the resin (P1) in the hard-mask forming composition is preferably 70 to 100 mass %, more preferably 80 to 100 mass %, still more preferably 90 to 100 mass %, particularly preferably 95 to 100 mass %, and most preferably 100 mass %, based on the total mass of all resins contained in the hard-mask forming composition. In a case where the proportion is at least the lower limit value of the preferable range, etching resistance, crack resistance, and low outgassing property of the hard-mask forming composition are further improved.

The resin (P1) can be prepared by, for example, condensing the monomer from which the structural unit (u11) or the structural unit (u12) is derived, the monomer from which the structural unit (u2) is derived, and optionally, a monomer from which other structural units are derived in the presence of an acid catalyst or a base catalyst. The acid catalyst is not particularly limited, and examples thereof include hydrochloric acid, nitric acid, sulfuric acid, formic acid, oxalic acid, acetic acid, and the like.

<Compound (C1)>

The compound (C1) is a compound represented by General Formula (c-1).

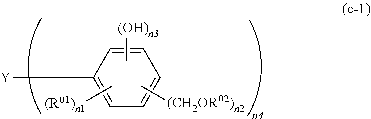

[In the formula, Y is an organic group. R⁰¹ is a hydrocarbon group having 1 to 40 carbon atoms. R⁰² is an alkyl group having 1 to 10 carbon atoms which may have an alkoxy group having 1 to 10 carbon atoms. n1 is an integer of 0 to 3, n2 is an integer of 1 to 4, n3 is an integer of 1 to 3, and n1 to n3 satisfy 2≤n1+n2+n3≤5. n4 is an integer of 3 or more, and a plurality of R⁰¹'s, R⁰²'s, n1's, n2's, and n3's may be the same as or different from each other, respectively. Here, the number of —CH₂OR⁰² in the formula is 6 or more as a whole of the compound (C1).]

In Formula, Y is an organic group, and more specifically, it is a hydrocarbon group which may have an n4-valent (trivalent or higher) substituent. The hydrocarbon group may be an aliphatic hydrocarbon group, or may be an aromatic hydrocarbon group.

The number of carbon atoms of the aliphatic hydrocarbon group is preferably 1 to 40, more preferably 1 to 30, still more preferably 1 to 25 carbon atoms, and particularly preferably 1 to 20 carbon atoms.

The aliphatic hydrocarbon group may be an aliphatic saturated hydrocarbon group, or may be an aliphatic unsaturated hydrocarbon group.

The aliphatic hydrocarbon group may be a chain aliphatic hydrocarbon group, or may be a cyclic aliphatic hydrocarbon group.

The aromatic hydrocarbon group preferably has 6 to 30 carbon atoms, more preferably has 6 to 25 carbon atoms, and still more preferably has 6 to 20 carbon atoms.

The aromatic hydrocarbon group is a hydrocarbon group having at least one aromatic ring. The aromatic ring is not particularly limited as long as it is a cyclic conjugated system having 4n+2 π electrons, and may be monocyclic or polycyclic. Specific examples of the aromatic ring include aromatic hydrocarbon rings such as benzene, naphthalene, anthracene, phenanthrene, and pyrene.

The aromatic ring contained in the aromatic hydrocarbon group may be an aromatic heterocyclic ring in which a part of carbon atoms constituting the aromatic hydrocarbon ring is substituted with a heteroatom. Examples of the hetero atom in the aromatic heterocyclic ring include an oxygen atom, a sulfur atom, a nitrogen atom, and the like. Specific examples of the aromatic heterocyclic ring include a pyrrolidine ring, a pyridine ring, a thiophene ring, and the like.

In the hydrocarbon group, a hydrogen atom of the hydrocarbon group may be substituted with a monovalent substituent, or a methylene group of the hydrocarbon group may be substituted with a divalent substituent.

Examples of the monovalent substituent include an alkoxy group, a halogen atom, a halogenated alkyl group, a hydroxyl group, a carbonyl group, a nitro group, an amino group, and the like.

Examples of the divalent substituent include a divalent hydrocarbon group represented by —O—, —C(═O)—O—, —O—C(═O)—, —C(═O)—, —O—C(═O)—O—, —C(═O)—NH—, —NH—, —NH—C(═NH)— (H may be substituted with a substituent such as alkyl group and acyl group), —S—, —S(═O)₂—, —S(═O)₂—O—, -General Formula-Y²¹—O—Y²²—, —Y²¹—O—, —Y²¹—C(═O)—O—, —C(═O)—O—Y²¹—, [Y²¹—C(═O)—O]_{m″}—Y²²—, -Y²¹—O—C(═O)—Y²²— or —Y²¹—S(═O)2-O—Y²²—[in Formula, Y²¹ and Y²² are each independently a divalent hydrocarbon group which may have a substituent, O is an oxygen atom, and m″ is an integer of 0 to 3], and the like.

Among these, in Formula, Y is preferably an aliphatic hydrocarbon group having 1 to 40 carbon atoms or an aromatic hydrocarbon group having 6 to 30 carbon atoms, and an aliphatic unsaturated hydrocarbon group having 1 to 40 carbon atoms or an aromatic hydrocarbon group having 6 to 30 carbon atoms is more preferable, and an aliphatic unsaturated hydrocarbon group having 1 to 20 carbon atoms or an aromatic hydrocarbon group having 6 to 20 carbon atoms is still more preferable, from a viewpoint of further improving etching resistance.

A suitable specific example of the organic group in Y is shown below. The symbol * represents a bonding site with a phenyl group in Formula (c-1).

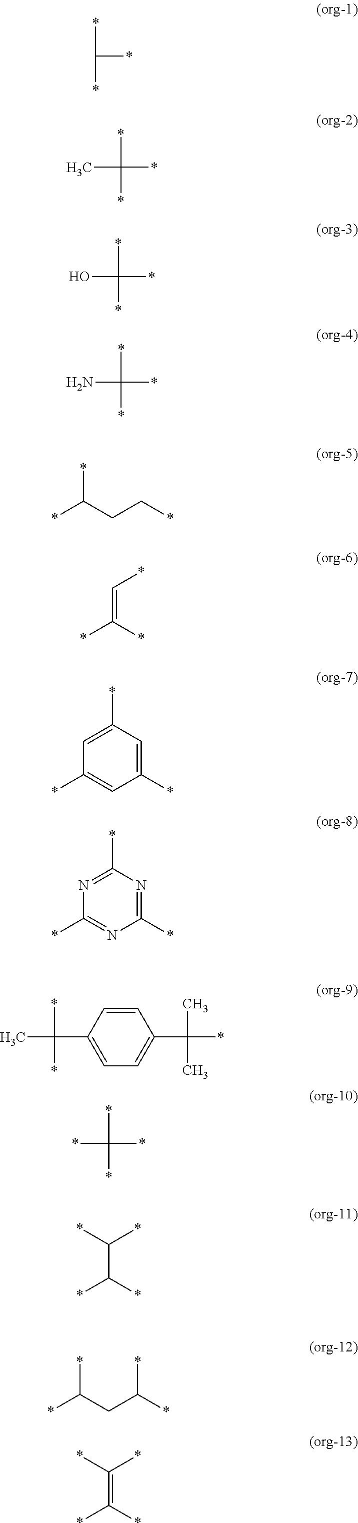

In Formula, among these, Y is preferably an organic group represented by any of Formulae (org-2), (org-6) to (org-9), and (org-13), more preferably an organic group represented by any of Formulae (org-6) to (org-9) and Formula (org-13), and still more preferably an organic group represented by Formula (org-9).

In Formula, R⁰¹ is a hydrocarbon group having 1 to 40 carbon atoms. Examples of the hydrocarbon group include a linear or branched alkyl group, a cyclic hydrocarbon group, or the like. The hydrocarbon group may be an aliphatic hydrocarbon group or an aromatic hydrocarbon group, and may be a polycyclic group or a monocyclic group.

In Formula, R⁰² is an alkyl group having 1 to 10 carbon atoms which may have an alkoxy group having 1 to 10 carbon atoms.

Specific examples of the alkyl group include a methyl group, an ethyl group, an n-propyl group, an n-butyl group, an n-pentyl group, an n-hexyl group, an n-heptyl group, an n-octyl group, an n-nonyl group, an n-decyl group, and the like. Examples of the alkoxy group include a group in which the alkyl group and an oxygen atom (—O—) are linked, and specific examples thereof include a methoxy group, an ethoxy group, a propoxy group, and a butoxy group.

In Formula, among these, R⁰² is preferably an alkyl group having 1 to 10 carbon atoms, more preferably a methyl group, an ethyl group, an n-propyl group, and an n-butyl group, still more preferably a methyl group and an ethyl group, and particularly preferably a methyl group.

In Formula, n1 is an integer of 0 to 3, n2 is an integer of 1 to 4, n3 is an integer of 1 to 3, and n1 to n3 satisfy 2≤n1+n2+n3≤5.

In Formula, n1 is an integer of 0 to 3, preferably 0 or 1, and more preferably 0.

In Formula, n2 is an integer of 1 to 4, preferably 1 or 2, and more preferably 2.

In Formula, n3 is an integer of 1 to 3, preferably 1 or 2, and more preferably 1.

In Formula, n4 is an integer of 3 or more, and a plurality of R⁰¹'s, R⁰²'s, n1's, n2's, and n3's may be the same as or different from each other, respectively. Here, “a plurality of R⁰¹'s and R⁰²'s may be the same as or different from each other” means that in a case where one phenyl group in Formula has a plurality of R⁰¹'s and R⁰²'s, they may be the same as or different from each other, and a plurality of phenyl groups in Formula may have different R⁰¹ or R⁰², respectively. In addition, “n1, n2, and n3 may be the same as or different from each other” means that a plurality of phenyl groups in Formula each may have a different number of substituents.

However, the number of —CH₂OR⁰² in Formula is 6 or more as a whole of the compound (C1).

In Formula, n4 is an integer of 3 or more, preferably 3 to 10, more preferably 3 to 6, still more preferably 3 or 4, and particularly preferably 3.

In Formula, in a case where n4 is 3, the compound (C1) has three phenyl groups that are bonded to Y in Formula. The three phenyl groups may have different numbers of hydroxy groups, may have R⁰¹ and —CH₂OR⁰², or may have different types of R⁰¹ and —CH₂OR⁰², respectively. In addition, R⁰¹ and —CH₂OR⁰² contained in one phenyl group may be different from each other.

Suitable specific examples of the compound (C1) are shown below.

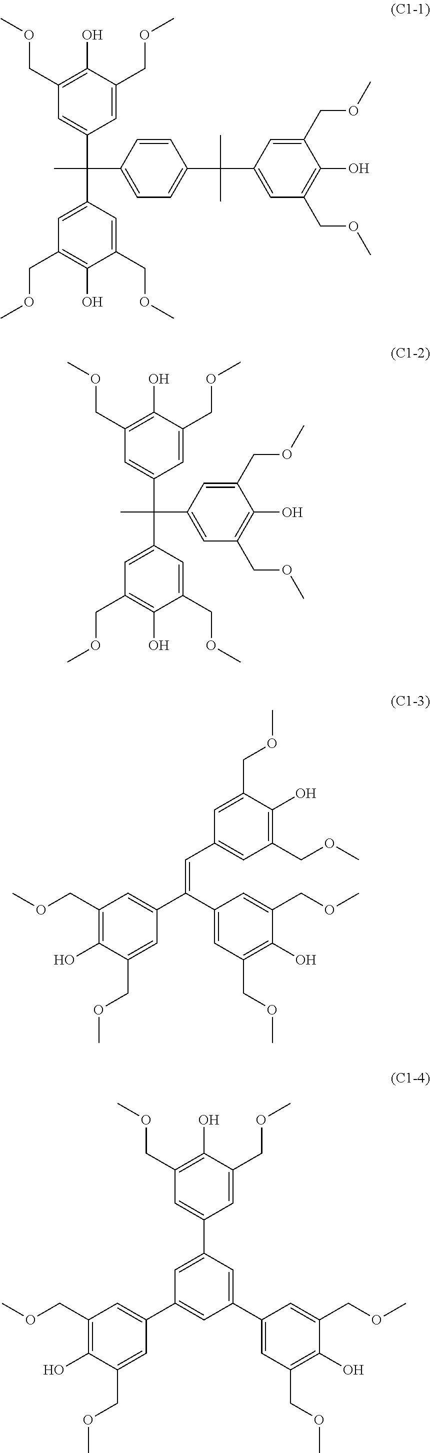

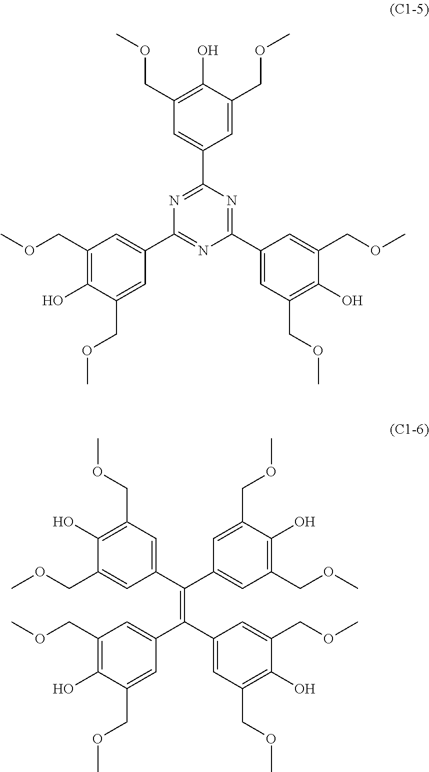

A component (C1) may be used alone, or two or more types thereof may be used in combination.

A content of the component (C1) in the hard-mask forming composition of the present embodiment is preferably 1 to 40 parts by mass, more preferably 5 to 35 parts by mass, and still more preferably 10 to 30 parts by mass, with respect to 100 parts by mass of the resin (P1).

If the content of the component (C1) is at least the preferable lower limit value, crosslinking reaction between the resin (P1) and the component (C1) proceeds more smoothly, and the crack resistance and the low outgassing property are further improved.

If the content of the component (C1) is not more than the preferable upper limit value, the generation of outgas derived from the component (C1) can be further suppressed.

<Optional Components>

The hard-mask forming composition of the present embodiment may contain other components in addition to the resin (P1) and the compound (C1) stated above. Examples of the other components include a phenol compound, a thermal acid generator, a surfactant, a crosslinking agent, a crosslinking acceleration catalyst, a photoacid generator, an absorbent, a rheology modifier, an adhesion aider, a solvent, and the like.

Phenol Compounds

The hard-mask forming composition of the present embodiment preferably contains a phenol compound.

By containing the phenol compound, the hard-mask forming composition of the present embodiment can further promote the crosslinking reaction between the resin (P1) stated above and the crosslinking agent to be stated later, and can further improve the low outgassing property.

The phenol compound in the present embodiment is a compound in which a hydroxy group is bonded to an aromatic ring. The aromatic ring is not particularly limited as long as it is a cyclic conjugated system having 4n+2 π electrons, and may be monocyclic or polycyclic. Specific examples of the aromatic ring include aromatic hydrocarbon rings such as benzene, naphthalene, anthracene, phenanthrene, and pyrene.

Specific examples of the phenol compound in the present embodiment include phenol; divalent phenol such as resorcinol, hydroquinone, and catechol; trivalent phenol such as pyrogallol; a compound having two hydroxyphenyl groups such as 4,4′-dihydroxybiphenyl, bisphenol A, 9,9-bis (4-hydroxy-3,5-dimethylphenyl) fluorene, 9,9-bis (4-hydroxy-3-methylphenyl) fluorene, and 1,1-bis (4-hydroxy-3-methylphenyl) cyclohexane; naphthol; a compound having two hydroxynaphthyl groups such as 1,1-methylene di-2-naphthol; pyrellol; a compound having two hydroxypyrenyl groups such as a compound represented by Chemical Formula (ph-1); and the like.

Among these, the phenol compound in the present embodiment is preferably a compound having two hydroxyphenyl groups, a compound having two hydroxynaphthyl groups, or a compound having two hydroxypyrenyl groups.

Specific examples of the phenol compound in the present embodiment are shown below.

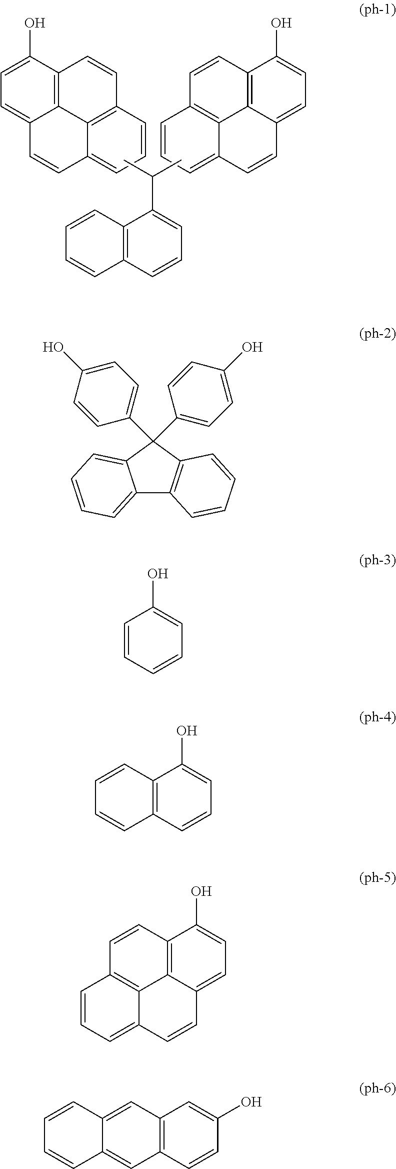

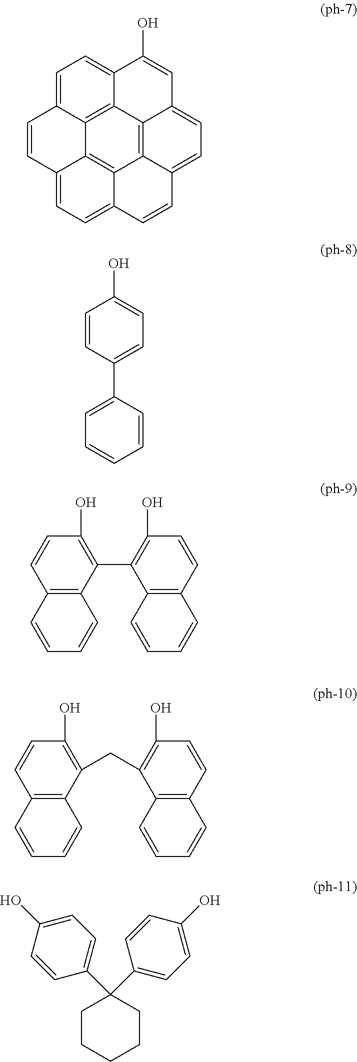

Among the these, the phenol compound in the present embodiment is preferably a compound represented by any of Formulae (ph-1), (ph-2), and (ph-9) to (ph-11), and more preferably a compound represented by Formula (ph-1) or (ph-2).

The phenol compound may be used alone, or two or more types may be used in combination.

A content of the phenol compound in the hard-mask forming composition of the present embodiment is preferably 1 to 90 parts by mass, more preferably 10 to 80 parts by mass, and still more preferably 20 to 70 parts by mass with respect to 100 parts by mass of the resin (P1).

If the content of the phenol compound is at least the preferable lower limit value, the crosslinking reaction between the resin (P1) and the component (C1) proceeds more smoothly, and the crack resistance and the low outgassing property are further improved.

If the content of the phenol compound is not more than the preferable upper limit value, the generation of outgas derived from the phenol compound can be further suppressed.

Thermal Acid Generator

The hard-mask forming composition of the present embodiment preferably contains a thermal acid generator (hereinafter, also referred to as component (T)”).

Examples of the component (T) include perfluoroalkyl sulfonate (trifluoromethane sulfonate, perfluorobutane sulfonate, and the like) hexafluorophosphate, boron trifluoride salt, boron trifluoride ether complex, and the like.

Examples of preferable component (T) include a compound (T1) represented by General Formula (T-1) and consisting of a cationic part and an anionic part (hereinafter, also referred to as “component (T1)”), and a compound (T2) represented by General Formula (T-2) and consisting of a cationic part and an anionic part (hereinafter, also referred to as “component (T2)”).

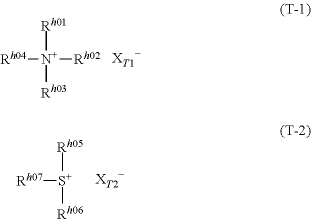

[In Formula (T-1), R^{h01} to R^{h04} are each independently a group selected from the group consisting of a hydrogen atom, an alkyl group having 1 to 20 carbon atoms, and an aryl group, and at least one of R^{h01} to R^{h04} is an aryl group. The alkyl group or aryl group may have a substituent. X_{T1}⁻ is a counter anion.

In Formula (T-2), R^{h05} to R^{h07} are each independently a group selected from the group consisting of an alkyl group having 1 to 20 carbon atoms and an aryl group, and at least one of R^{h05} to R^{h07} is an aryl group. The alkyl group or aryl group may have a substituent. X_{T2}⁻ is a counter anion.]

. . . Regarding Anionic Part of Component (T1) and Component (T2)

Examples of X_{T1}⁻ in Formula (T-1) and X_{T2}⁻ in Formula (T-2) include a hexafluorophosphate anion, a perfluoroalkyl sulfonic acid anion (trifluoromethane sulfonate anion, perfluorobutane sulfonate anion), tetrakis (pentafluorophenyl) borate anion, and the like.

Among these, a perfluoroalkyl sulfonate anion is preferable, a trifluoromethane sulfonate anion or a perfluorobutane sulfonate anion is more preferable, and a trifluoromethane sulfonate anion is still more preferable.

. . . Regarding Cationic Part of Component (T1)

In Formula (T-1), the alkyl group for R^{h01} to R^{h04} is an alkyl group having 1 to 20 carbon atoms, preferably having 1 to 10 carbon atoms, more preferably having 1 to 5 carbon atoms, and still more preferably a linear or branched alkyl group having 1 to 5 carbon atoms. Specific examples thereof include a methyl group, an ethyl group, a propyl group, an isopropyl group, an n-butyl group, an isobutyl group, a tert-butyl group, a pentyl group, an isopentyl group, a neopentyl group, and the like, and among these, a methyl group and an ethyl group are preferable.

The alkyl group for R^{h01} to R^{h04} may have a substituent. Examples of the substituent include an alkoxy group, a halogen atom, a halogenated alkyl group, a hydroxyl group, a carbonyl group, a nitro group, an amino group, a cyclic group, and the like.

The alkoxy group as the substituent of the alkyl group is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group and an ethoxy group.

Examples of the halogen atom as the substituent of the alkyl group include a fluorine atom, a chlorine atom, a bromine atom, an iodine atom, and the like, and the fluorine atom is preferable.

Examples of the halogenated alkyl group as the substituent of the alkyl group include an alkyl group having 1 to 5 carbon atoms, for example, a group in which a part or all of hydrogen atoms such as methyl group, ethyl group, propyl group, n-butyl group, and tert-butyl group is substituted with the halogen atom.

A carbonyl group as the substituent of the alkyl group is a group (>C═O) that substitutes a methylene group (—CH₂—) constituting the alkyl group.

Examples of the cyclic group as the substituent of the alkyl group include an aromatic hydrocarbon group and an alicyclic hydrocarbon group (which may be polycyclic or monocyclic). Examples of the aromatic hydrocarbon group here include the same as the aryl group for R^{h01} R^{h04} to be stated later. In the alicyclic hydrocarbon group here, as the monocyclic alicyclic hydrocarbon group, a group obtained by removing at least one hydrogen atom from a monocycloalkane is preferable. As the monocycloalkane, those having 3 to 6 carbon atoms are preferable, and specific examples thereof include cyclopentane, cyclohexane, and the like. In addition, as the polycyclic alicyclic hydrocarbon group, a group obtained by removing at least one hydrogen atom from polycycloalkane is preferable, and as the polycycloalkane, those having 7 to 30 carbon atoms are preferable. Among these, as the polycycloalkane, a polycycloalkane having a polycyclic skeleton of a crosslinking ring system such as adamantane, norbornane, isobomane, tricyclodecane, and tetracyclododecane; and a polycycloalkane having a polycyclic skeleton of a condensed ring system such as a cyclic group having a steroid skeleton are more preferable.

In Formula (T-1), the aryl group for R^{h01} to R^{h04} is a hydrocarbon group having at least one aromatic ring.

The aromatic ring is not particularly limited as long as it is a cyclic conjugated system having 4n+2 π electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms.

Specific examples of the aromatic ring include an aromatic hydrocarbon ring such as benzene, naphthalene, anthracene, and phenanthrene; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyridine ring, a thiophene ring, and the like.

Specific examples of the aryl group for R^{h01} to R^{h04} include a group obtained by removing one hydrogen atom from the aromatic hydrocarbon ring or aromatic heterocyclic ring; a group obtained by removing one hydrogen atom from an aromatic compound (for example, biphenyl, fluorene, and the like) containing two or more aromatic rings; a group in which one hydrogen atom of the aromatic hydrocarbon ring or aromatic heterocyclic ring is substituted with an alkylene group (for example, arylalkyl group such as benzyl group, phenethyl group, 1-naphtylmethyl group, 2-naphtylmethyl group, 1-naphtylethyl group, 2-naphtylethyl group, and the like); and the like. An alkylene group to be bonded to the aromatic hydrocarbon ring or the aromatic heterocyclic ring preferably has 1 to 4 carbon atoms, more preferably has 1 to 2 carbon atoms, and particularly preferably has 1 carbon atom. Among these, a group obtained by removing one hydrogen atom from the aromatic hydrocarbon ring or aromatic heterocyclic ring and a group in which one hydrogen atom of the aromatic hydrocarbon ring or aromatic heterocyclic ring is substituted with an alkylene group are preferable, and a group obtained by removing one hydrogen atom from the aromatic hydrocarbon ring and a group in which one hydrogen atom of the aromatic hydrocarbon ring is substituted with an alkylene group are still more preferable.

The aryl group for R^{h01} to R^{h04} may have a substituent. Examples of the substituent include an alkyl group, an alkoxy group, a halogen atom, a halogenated alkyl group, a hydroxyl group, a carbonyl group, a nitro group, an amino group, a cyclic group, an alkylcarbonyloxy group, and the like.

The alkyl group as the substituent of the aryl group is preferably an alkyl group having 1 to 5 carbon atoms, and preferably a methyl group, an ethyl group, a propyl group, an n-butyl group, and a tert-butyl group.

The description of the alkoxy group, the halogen atom, the halogenated alkyl group, the carbonyl group, and the cyclic group as the substituent of the aryl group is the same as the description of the alkoxy group, the halogen atom, the halogenated alkyl group, the carbonyl group, and the cyclic group as the substituent of the alkyl group stated above.

In the alkylcarbonyloxy group as a substituent of the aryl group, the alkyl part preferably has 1 to 5 carbon atoms, examples of the alkyl part include a methyl group, an ethyl group, a propyl group, an isopropyl group, and the like, and among these, a methyl group and an ethyl group are preferable, and a methyl group is more preferable.

However, in Formula (T1), at least one of R^{h01} to R^{h04} is an aryl group which may have a substituent.

Hereinafter, preferable cations as the cationic part of the component (T1) are shown below.

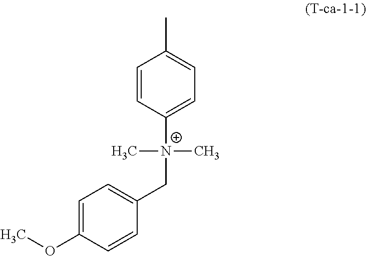

. . . Regarding Cationic Part of Component (T2)

In Formula (T-2), the description of the alkyl group and the aryl group for R^{h05} to R^{h07} is the same as the description of the alkyl group and aryl group for R^{h01} to R^{h04} stated above, respectively.

However, in Formula (T-2), at least one of R^{h05} to R^{h07} is an aryl group which may have a substituent.

Hereinafter, preferable cations as the cationic part of the component (T2) are shown below.

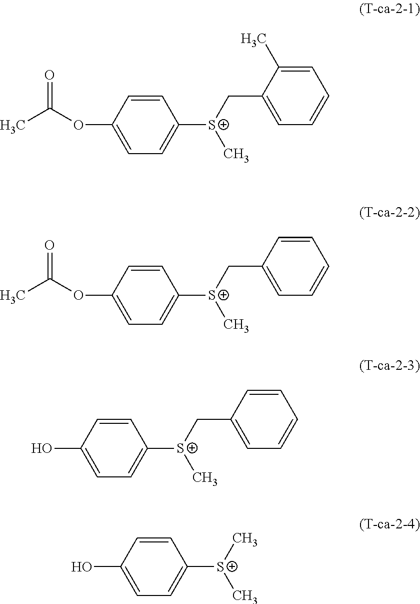

The component (T) contained in the hard-mask forming composition of the present embodiment may be one type, or may be two or more types.

Among these, the hard-mask forming composition of the present embodiment preferably contains the component (T1). As the component (T1), for example, a commercially available product having a product name of TAG-2689 (manufactured by KING INDUSTRY) may be used.

In a case where the hard-mask forming composition of the present embodiment contains the component (T), a content of the component (T) is preferably 0.01 to 20 parts by mass, more preferably 0.1 to 10 parts by mass, and still more preferably 0.5 to 5 parts by mass, with respect to 100 parts by mass of the total amount of the resin (P1).

In a case where the content of the component (T) is within the preferable range, reactivity of the crosslinking reaction is further enhanced, and the low outgassing property is further improved.

Surfactant

The hard-mask forming composition of the present embodiment preferably further contains a surfactant.

Examples of the surfactant include a nonionic surfactant encompassing: polyoxyethylene alkyl ethers such as polyoxyethylene lauryl ether, polyoxyethylene stearyl ether, polyoxyethylene cetyl ether, polyoxyethylene oleyl ether; polyoxyethylene alkyl allyl ethers such as polyoxyethylene octyl phenol ether and polyoxyethylene nonyl phenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorinated surfactants such as F-top [registered trademark] EF 301, EF 303, and EF 352 [collectively manufactured by Mitsubishi Materials Electronic Chemicals Co., Ltd. (formerly Tochem Products), product names], Megafac [registered trademark] F171, F173, R-30, and R-40 [collectively manufactured by DIC Corporation (formerly Dai Nippon Ink Co., Ltd.), product names], Fluorad FC430 and FC431 (collectively manufactured by Sumitomo 3M Co., Ltd., product names), Asahi Guard [registered trademark] AG710, Surflon [registered trademark] S-382, SC101, SC102, SC103, SC104, SC105, and SC106 (collectively manufactured by Asahi Glass Co., Ltd., product names); Organosiloxane Polymer KP341 (manufactured by Shin-Etsu Chemical Co., Ltd.); and the like.

The surfactant contained in the hard-mask forming composition of the present embodiment may be one type or two or more types.

Among these, the hard-mask forming composition of the present embodiment preferably contains a fluorinated surfactant.

In a case where the hard-mask forming composition of the present embodiment contains a surfactant, a content of the surfactant is preferably 0.01 to 20 parts by mass, more preferably 0.05 to 5 parts by mass, and still more preferably 0.08 to 1 part by mass, with respect to 100 parts by mass of the total amount of the resin (P1).

In a case where the content of the surfactant is within the preferable range, a film surface when applying the hard-mask forming composition is made uniform, and striations (application defects such as wavy and striped patterns) can be further prevented.

Crosslinking Agent

The hard-mask forming composition of the present embodiment may contain a crosslinking agent other than the compound (C1) stated above. Examples of the crosslinking agent include an amino-based crosslinking agent such as glycoluril having a methylol group or an alkoxymethyl group; a melamine-based crosslinking agent; and the like. Specific examples include Nikalac (registered trademark) series (Nikalac MX270 and the like) manufactured by Sanwa Chemical Co., Ltd. A blending amount of the crosslinking agent component is preferably 1 to 50 parts by mass, and more preferably 1 to 40 parts by mass, based on 100 parts by mass of all resin components in the hard-mask forming composition.

The crosslinking agent may be used alone, or two or more types thereof may be used in combination.

Crosslinking Acceleration Catalyst

Examples of the crosslinking acceleration catalyst include acidic compounds such as p-toluenesulfonic acid, trifluoromethanesulfonic acid, pyridinium p-tolue nesulfonic acid, salicylic acid, sulfosalicylic acid, citric acid, benzoic acid, hydroxybenzoic acid, and naphthalenecarboxylic acid, and the like.

The crosslinking acceleration catalyst may be used alone, or two or more types thereof may be used in combination.

Photoacid Generator

Examples of the photoacid generator include onium salt photoacid generators such as bis (4-t-butylphenyl) iodonium trifluoromethanesulfonate and triphenylsulfonium trifluoromethanesulfonate; halogen-containing compound photoacid generators such as phenyl-bis (trichloromethyl)-s-triazine; sulfonic acid photoacid generators such as benzoin tosylate and N-hydroxysuccinimide trifluoromethanesulfonate; and the like. A blending amount of the photoacid generator is preferably 0.2 to 10 parts by mass and more preferably 0.4 to 5 parts by mass, based on 100 parts by mass of all resin components in the hard-mask forming composition.

The photoacid generator may be used alone, or two or more types may be used in combination.

Absorbent

Examples of the absorbent include commercially available absorbents listed in “Technology and Market for Industrial Dyes” (published by CMC) and “Dyes Handbook” (edited by the Society of Synthetic Organic Chemistry), for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; C. I. Pigment Brown 2; and the like. A blending amount of the absorbent is preferably 10 parts by mass or less, and more preferably 5 parts by mass or less, based on 100 parts by mass of all resin components in the hard-mask forming composition.

The absorbent may be used alone, or two or more types may be used in combination.

Rheology Modifier

Examples of the rheology modifier include phthalic acid derivatives such as dimethyl phthalate, diethyl phthalate, diisobutyl phthalate, dihexyl phthalate, and butyl isodecyl phthalate; adipic acid derivatives such as dinormal butyl adipate, diisobutyl adipate, diisooctyl adipate, and octyl decyl adipate; maleic acid derivatives such as dinormal butyl malate, diethyl malate, and dinonyl malate; oleic acid derivatives such as methyl oleate, butyl oleate, and tetrahydrofurfuryl oleate; and stearic acid derivatives such as normal butyl stearate and glyceryl stearate. A blending amount of the rheology modifier is preferably less than 30 parts by mass, based on 100 parts by mass of all resin components in the hard-mask forming composition.

The rheology modifier may be used alone, or two or more types may be used in combination.

Adhesion Aider

Examples of the adhesion aider include chlorosilanes such as m-trimethylchlorosilane, dimethylvinylchlorosilane, methyldiphenylchlorosilane, and chloromethyldimethylchlorosilane; alkoxysilanes such as trimethylmethoxysilane, dimethyldiethoxysilane, methyldimethoxysilane, dimethylvinylethoxysilane, diphenyldimethoxysilane, and phenyltriethoxysilane; silazanes such as hexamethyldisilazane, N, N′-bis(trimethylsilyl) urea, dimethyltrimethylsilylamine, and trimethylsilylimidazole; silanes such as vinyltrichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; urea such as 1,1-dimethylurea and 1,3-dimethylurea; thiourea compounds; and the like. A blending amount of the adhesion aider is preferably less than 5 parts by mass, and more preferably less than 2 parts by mass, based on 100 parts by mass of all resin components in the hard-mask forming composition. The adhesion aider may be used alone, or two or more types may be used in combination.

Solvent

The solvent is used to dissolve the resin (P1), the compound (C1), and the optional components.

Examples of the solvent include lactones such as γ-butyrolactone; ketones such as acetone, methyl ethyl ketone, cyclohexanone, methyl-n-pentyl ketone, methyl isopentyl ketone, 2-heptanone, or the like; polyhydric alcohols such as ethylene glycol, diethylene glycol, propylene glycol, dipropylene glycol, or the like; derivatives of polyhydric alcohols of compounds having an ester bond such as ethylene glycol monoacetate, diethylene glycol monoacetate, propylene glycol monoacetate, or dipropylene glycol monoacetate, compounds having an ether bond such as monoalkyl ethers or monophenyl ether such as monomethyl ether, monoethyl ether, monopropyl ether, monobutyl ether, or the like of the polyhydric alcohol or the compound having the ester bond, or the like [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, ethyl ethoxypropionate or the like; aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, mesitylene or the like; dimethyl sulfoxide (DMSO); and the like.

Among these, PGME, PGMEA, ethyl lactate, butyl lactate, γ-butyrolactone, cyclohexanone, mixed solvents thereof, and the like are preferable, from a viewpoint of further improving the leveling property.

The solvent may be used alone, or may be a mixed solvent of two or more types of solvents. Examples of the mixed solvent include a mixed solvent of PGME and γ-butyrolactone.

A use amount of the solvent is not particularly limited, and is appropriately set to a concentration applicable to a substrate or the like, depending on the thickness of a coating film. For example, the solvent may be blended so that the resin component concentration in the hard-mask forming composition falls within a range of 1% to 50% by mass, and preferably a range of 15% to 35% by mass.

The hard-mask forming composition of the present embodiment contains a resin (P1) and a compound (C1).

Since the resin (P1) has a structural unit (u11) or a structural unit (u12) having relatively high rigidity and a structural unit (u2) having an aromatic ring and a polar group, the resin (P1) has excellent etching resistance.

Since the compound (C1) has a specific structure having high reactivity with the resin, the crosslinking reaction between the resin and the compound (C1) can proceed smoothly. Therefore, in the hard mask layer formed by using the hard-mask forming composition of the present embodiment, the crosslinking reaction proceeds sufficiently, the entanglement of molecules increases, and the crack resistance is excellent.

In addition, by using the resin (P1) and the compound (C1) in combination, the crosslinking reaction proceeds more smoothly and the generation of outgas can be suppressed due to insufficient crosslinking reaction, and thus low outgassing property is excellent.

As described above, the hard-mask forming composition of the embodiment can realize high crack resistance and low outgassing property while maintaining high etching resistance.

(Method for Manufacturing Electronic Component)

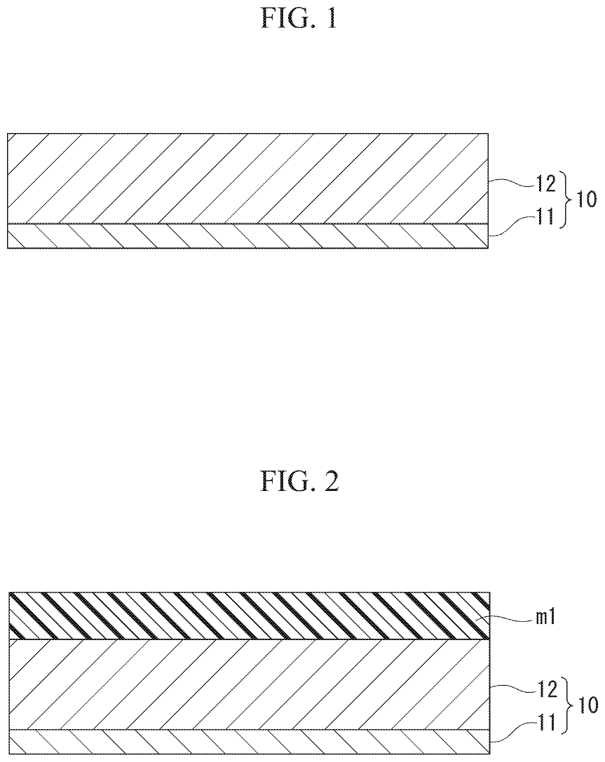

Specific examples of the method for manufacturing an electronic component according to second to fourth aspects of the present invention will be described with reference to FIGS. 1 to 8.

### First Embodiment

The method for manufacturing an electronic component of the present embodiment includes steps of:

forming a hard mask layer (m1) on a support using the hard-mask forming composition according to the first aspect stated above (hereinafter, referred to as “step (i-i)”); and processing the support using the hard mask layer (m1) as a mask (hereinafter, referred to as “step (i-a)”).

FIG. 1 shows a support 10 formed by a substrate 11 and a processing layer 12.

First, the hard mask layer (m1) is formed on the support 10 using the hard-mask forming composition according to the first aspect stated above (FIG. 2; step (i-i)).

[Step (i-i)]

Step (i-i) is a step of forming the hard mask layer (m1) on the support 10 using the hard-mask forming composition according to the first aspect stated above.

The substrate 11 is not particularly limited and a known substrate in the related art can be used. Examples thereof include a substrate for an electronic component, a substrate on which a predetermined wiring pattern is formed, and the like. More specifically, examples of the substrate include silicon wafers, metal substrates made of copper, chromium, iron, and aluminum, glass substrates, and the like. As a material of the wiring pattern, copper, aluminum, nickel, gold, and the like can be used.

Examples of the processing layer 12 include various Low-k films such as films of Si, SiO₂, SiON, SiN, p-Si, α-Si, W, W-Si, Al, Cu and Al-Si, stopper films thereof, and the like. The processing layer 12 usually has a thickness of 50 to 10,000 nm. In addition, in a case of performing deep processing, the thickness of the processing layer 12 may fall within a range of 1,000 to 10,000 nm.

The support 10 may not have the processing layer 12, but in a case of forming the processing layer 12, the substrate 11 and the processing layer 12 are usually made of different materials.

The hard mask layer (m1) is formed using the hard-mask forming composition according to the first aspect stated above. Specifically, the hard-mask forming composition according to the first aspect stated above is applied onto the support 10 by spin coating or the like. Subsequently, the hard mask layer (m1) is formed by baking and curing. Baking is typically performed within a range of 100° C. to 500° C., preferably within a range of 200° C. to 450° C., and more preferably within a range of 250° C. to 400° C. The baking temperature is adjusted to be equal to or less than the upper limit value of the range stated above, thus it is possible to suppress decrease in etching resistance due to the oxidation reaction of the resin. In addition, the baking temperature is adjusted to be at least the lower limit value of the range stated above, thus it is possible to suppress deterioration due to high temperature in the process to be stated later. The baking time typically falls within a range of 10 to 600 seconds, preferably a range of 30 to 300 seconds, and more preferably a range of 50 to 200 seconds.

The thickness of the hard mask layer (m1) is not particularly limited, and can be appropriately set according to the thickness of the processing layer 12. The thickness of the hard mask layer (m1) may fall within a range of 30 to 20,000 nm. In addition, in a case of performing deep processing, the thickness of the hard mask layer (m1) is preferably 1,000 nm or more. In this case, the thickness of the hard mask layer (m1) falls within preferably a range of 1,000 to 20,000 nm, and more preferably a range of 1,000 to 15,000 nm.

[Step (i-a)]

Step (i-a) is a step of processing the support 10 using the hard mask layer (m1) as a mask. The support 10 can be processed by, for example, performing etching using the hard mask layer (m1) as a mask. A method of etching is not particularly limited, and common dry etching and the like can be used.

### Second Embodiment

The method for manufacturing an electronic component of the present embodiment includes steps of:

forming a hard mask layer (m1) on a support using the hard-mask forming composition according to the first aspect stated above (hereinafter, referred to as “step (ii-i)”);

forming a hard mask layer (m2) made of an inorganic material on the hard mask layer (m1) (hereinafter, referred to as “step (ii-ii)”);

forming a resist film on the hard mask layer (m2) (hereinafter, referred to as “step (ii-iii)”);

exposing the resist film and developing the exposed film to form a resist pattern on the hard mask layer (m2) (hereinafter, referred to as “step (ii-iv)”);

etching the hard mask layer (m2) using the resist pattern as a mask to form an inorganic pattern (hereinafter, referred to as “step (ii-v)”);

etching the hard mask layer (m1) using the inorganic pattern as a mask to form a resin pattern (hereinafter, referred to as “step (ii-vi)”); and

processing the support using the resin pattern as a mask (hereinafter, referred to as “step (ii-vii)”).

FIG. 1 shows a support 10 formed by a substrate 11 and a processing layer 12. First, the hard mask layer (m1) is formed on the support 10 using the hard-mask forming composition according to the first aspect stated above (FIG. 2; step (ii-i)).

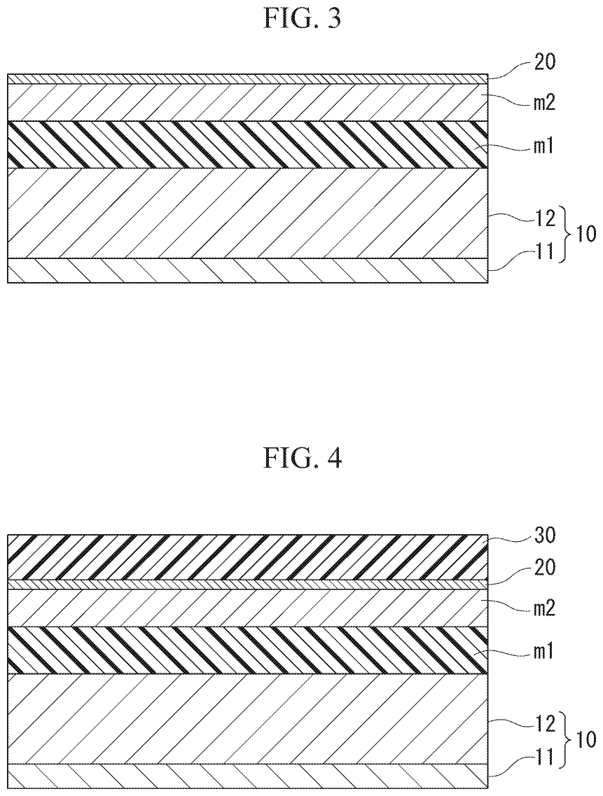

Subsequently, the hard mask layer (m2) made of an inorganic material is formed on the hard mask layer (m1) (FIG. 3; step (ii-ii)). In addition, an antireflective film (BARC) 20 is formed on the hard mask layer (m2) if needed.

Subsequently, a resist film 30 is formed on the hard mask layer (m2) using a resist composition (FIG. 4; step (ii-iii)).

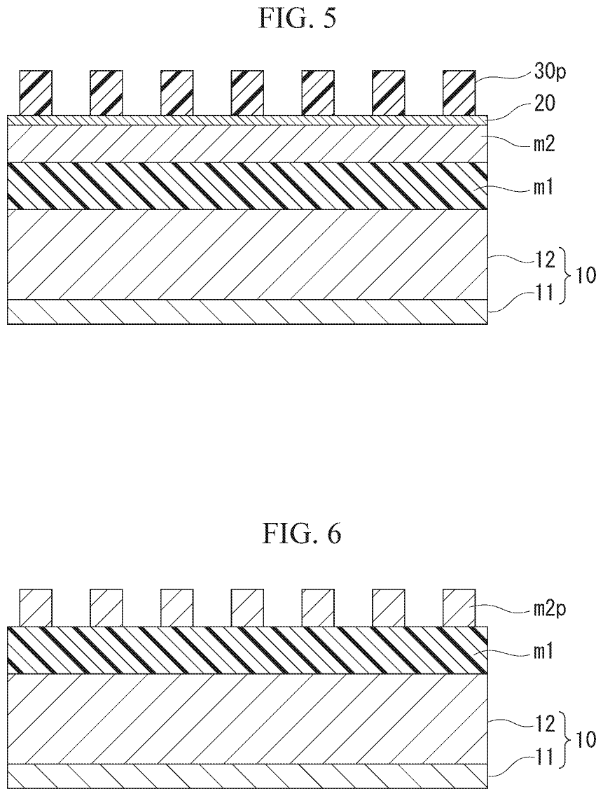

Subsequently, a resist film is exposed and developed to form a resist pattern 30p on the hard mask layer (m2) (FIG. 5; step (ii-iv)).

Subsequently, the hard mask layer (m2) is etched with the resist pattern 30p as a mask to form an inorganic pattern (m2p) (FIG. 6; step (ii-v)).

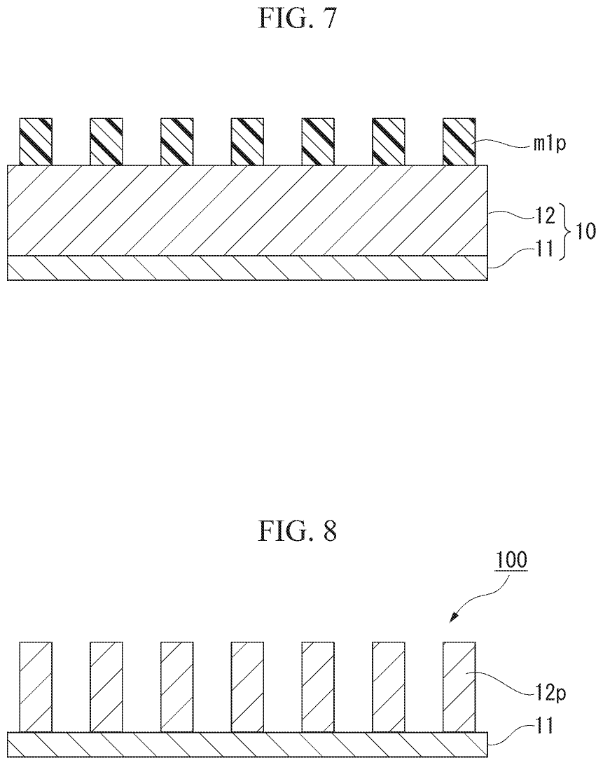

Subsequently, the hard mask layer (m1) is etched with the inorganic pattern (m2p) as a mask to form a resin pattern (m1p) (FIG. 7; step (ii-vi)).

Subsequently, the support 10 is processed with the resin pattern (m1p) as a mask to form a pattern 12p (FIG. 8; step (ii-vii)).

Thus, an electronic component 100 provided with the pattern 12p on the substrate 11 can be manufactured.

[Step (ii-i)]

Step (ii-i) is the same as step (i-i) stated above.

[Step (ii-ii)]

Step (ii-ii) is a step of forming the hard mask layer (m2) made of an inorganic material on the hard mask layer (m1).

The inorganic material for forming the hard mask layer (m2) is not particularly limited, and known materials in the related art can be used. Examples of the inorganic material include a silicon oxide film (SiO₂ film), a silicon nitride film (Si₃N₄ film), a silicon oxynitride film (SiON film), and the like. Among these, a SiON film having a high effect as an antireflective film is preferable. The hard mask layer (m2) can be formed by using a CVD method, an ALD method, and the like. The thickness of the hard mask layer (m2) is, for example, about 5 to 200 nm, and preferably about 10 to 100 nm.

In a case where the CVD method or the ALD method is used to form the hard mask layer (m2), a temperature becomes high (about 400° C.), and thus the hard mask layer (m1) is required to have high temperature resistance. The hard-mask forming composition according to the first aspect stated above is excellent in heat resistance, and does not easily cause shrinkage even when exposed to a high temperature of about 400° C. Therefore, it can be suitably used in combination with the inorganic hard mask layer formed by the CVD method or the ALD method.

After forming the hard mask layer (m2), if needed, the antireflective film (BARC) 20 may be formed on the hard mask layer (m2). The BARC 20 may be an organic BARC, or may be an inorganic BARC. The BARC can be formed using known methods in the related art.

[Step (ii-iii)]

Step (ii-iii) is a step of forming the resist film 30 on the hard mask layer (m2) using a resist composition.

The resist composition is not particularly limited, and those proposed as a resist material suitable for a method using an exposure step can be generally used. The resist composition may be positive-tone or negative-tone. Examples of the resist composition include those containing a base component of which solubility in a developer changes due to action of the acid, and an acid generator component that generates the acid upon exposure.

The formation of the resist film 30 is not particularly limited, and a method generally used for forming the resist film 30 may be used. For example, the resist composition is applied by a spinner on the hard mask layer (m2) (in a case where the BARC 20 is formed, it is applied on the BARC 20 on the hard mask layer (m2)), and baked (post-apply baking (PAB)), for example, at a temperature of 80° C. to 150° C. for 40 to 120 seconds, and preferably for 60 to 90 seconds, thereby forming the resist film 30.

A thickness of the resist film 30 is not particularly limited, but it is generally about 30 to 500 nm.

[Step (ii-iv)]

Step (ii-iv) is a step of exposing the resist film 30 and developing thereof to form the resist pattern 30p on the hard mask layer (m2).

The resist film 30 can be exposed using an exposure apparatus such as an ArF exposure apparatus, a KrF exposure apparatus, an electron beam drawing apparatus, an EUV exposure apparatus, and the like. A wavelength used for exposure is not particularly limited, and exposure can be performed using ArF excimer laser, KrF excimer laser, F₂ excimer laser, EUV (extreme ultraviolet), VUV (vacuum ultraviolet), EB (electron beam), radiation such as X-ray and soft X-ray, and the like. The resist film 30 may be exposed by normal exposure (dry exposure) performed in an inert gas such as air and nitrogen, or by Liquid Immersion Lithography.

For example, the resist film 30 is selectively exposed by exposure through a photomask (mask pattern) on which a predetermined pattern is formed, by drawing with direct irradiation of the electron beam without a photomask, or the like. Subsequently, the resist film 30 is baked (post-exposure baking (PEB)), for example, at a temperature of 80° C. to 150° C. for 40 to 120 seconds, and preferably for 60 to 90 seconds.

Subsequently, the resist film 30 is developed. A developer used for the development can be appropriately selected from commonly used developers, depending on a type of the resist composition and a development method. For example, in a case of employing an alkali development process, an alkali developer is used, and in a case of employing a solvent development process, a developer (organic developer) containing an organic solvent is used.

Examples of the alkali developer used for development in the alkali development process include an aqueous solution of 0.1% to 10% by mass of tetramethylammonium hydroxide (TMAH).

Examples of the organic solvent contained in the organic developer used for development in the solvent development process include polar solvents such as a ketone solvent, an ester solvent, an alcohol solvent, a nitrile solvent, an amide solvent, an ether solvent, and the like; a hydrocarbon solvent; and the like.

The development process can be carried out by a known development method, such as a method of immersing the support in the developer for a fixed time (dipping); a method of raising the developer on a surface of the support by surface tension and standing still for a fixed time (paddling); a method of spraying the developer on the surface of the support (spraying); a method of continuously applying the developer while scanning the developer-coating nozzle at constant speed on the support rotating at constant speed (dynamic dispensing); or the like.

After the development process, the developed film is preferably rinsed. In a case of the alkali development process, the developed film is preferably rinsed using pure water, and in a case of the solvent development process, the developed film is preferably rinsed using a rinse solution containing an organic solvent.

Meanwhile, in a case of the solvent development process, after the development or rinsing, the developer or rinse solution adhering on the pattern may be removed with a supercritical fluid.

After the development or rinsing, the film is dried. In addition, depending on the case, the film may be baked (post baking) after the development.

Therefore, the resist pattern 30p can be formed on the hard mask layer (m2).

[Step (ii-v)]

Step (ii-v) is a step of etching the hard mask layer (m2) using the resist pattern 30p as a mask to form the inorganic pattern (m2p).

A method of etching the hard mask layer (m2) is not particularly limited, and for example, common dry etching can be used. Examples of the etching method include chemical etching such as down flow etching, chemical dry etching, or the like; physical etching such as sputter etching, ion beam etching, or the like; and chemical-physical etching such as RIE (reactive ion etching), or the like.

For example, in parallel plate RIE, a multilayer laminate is placed in a chamber of an RIE apparatus, and necessary etching gas is introduced. When a high frequency voltage is applied to a holder of the multilayer laminate placed in parallel with an upper electrode in the chamber, the etching gas is made to plasma. Etching species including charged particles such as positive and negative ions or electrons, and neutral active species are present in the plasma. When these etching species are adsorbed to a lower resist layer, a chemical reaction occurs. Reaction products leave a surface and are exhausted to the outside, thereby performing etching.

Examples of the etching gas used for etching the hard mask layer (m2) include halogen-based gas. Examples of the halogen-based gas include hydrocarbon gas in which part or all of hydrogen atoms are substituted with halogen atoms such as fluorine atoms, chlorine atoms, or the like. More specifically, examples thereof include fluorinated carbon-based gas such as tetrafluoromethane (CF₄) gas and trifluoromethane (CHF₃) gas; carbon chloride-based gas such as tetrachloromethane (CCl₄) gas; and the like.

[Step (ii-vi)]

Step (ii-vi) is a step of etching the hard mask layer (m1) using the inorganic pattern (m2p) as a mask to form the resin pattern (m1p).

A method of etching is not particularly limited, and common dry etching and the like can be used in the same manner as in the step (ii-vi). Examples of the etching gas used for etching the hard mask layer (m1) include oxygen gas, sulfur dioxide gas, halogen-based gas, and the like. For example, oxygen plasma etching using oxygen gas as the etching gas and the like are preferable.

[Step (ii-vii)]

Step (ii-vii) is a step of processing the support 10 using the resin pattern (m1p) as a mask.

The support 10 can be processed by, for example, etching the processing layer 12 using the resin pattern (m1p) as a mask. A method of etching is not particularly limited, and common dry etching and the like can be used in the same manner as in the step (ii-vi). Examples of the etching gas used for etching the processing layer 12 include halogen-based gas.

In the method for manufacturing an electronic component according to the present embodiment, the hard mask layer (m1) can be thickened (1 μm or more) since the hard mask layer (m1) is formed using the hard-mask forming composition according to the first aspect stated above. Accordingly, the resin pattern formed from the hard mask layer (m1) can be suitably used as a mask for deep processing.

The method for manufacturing an electronic component by the three-layer resist method has been described above, but the electronic component may be manufactured by the two-layer resist method. In that case, the resist film 30, instead of the hard mask layer (m2), is formed on the hard mask layer (m1).

The resist film 30 is exposed and developed to form the resist pattern 30p on the hard mask layer (m1) in the same manner as in step (iv).

Subsequently, the hard mask layer (m1) is etched with the resist pattern 30p as a mask to form the resin pattern (m1p) in the same manner as in step (vi).

After that, the support 10 is processed using the resin pattern (m1p) as a mask to form the pattern 12p in the same manner as in step (vii).

Thus, the electronic component can also be manufactured by the two-layer resist method.

Therefore, the present invention also provides a method for manufacturing an electronic component, including steps of:

forming the hard mask layer (m1) on the support using the hard-mask forming composition according to the first aspect stated above;

forming the resist film on the hard mask layer (m1);

exposing the resist film and developing thereof to form the resist pattern on the hard mask layer (m1);

etching the hard mask layer (m1) using the resist pattern as a mask to form the resin pattern; and

processing the support using the resin pattern as a mask.

### Third Embodiment

The method for manufacturing an electronic component of the present embodiment includes steps of:

forming a hard mask layer (m1) on a support using the hard-mask forming composition according to the first aspect stated above (hereinafter, referred to as “step (iii-i)”);

forming an inorganic pattern made of an inorganic material on the hard mask layer (m1) (hereinafter, referred to as “step (iii-v)”);

the hard mask layer (m1) is etched using the inorganic pattern as a mask to form a resin pattern (hereinafter, referred to as “step (iii-vi)”); and

processing the support using the resin pattern as a mask (hereinafter, referred to as “step (iii-vii)”).

The method for manufacturing an electronic component according to the fourth aspect is the same as the method for manufacturing an electronic component according to the third aspect, except that the inorganic pattern made of an inorganic material is formed directly on the hard mask layer (m1) without forming the resist film.

Hereinafter, a specific example of the method for manufacturing an electronic component according to the present embodiment will be described with reference to FIGS. 1, 2, and 6 to 8. However, the manufacturing method according to the present embodiment is not limited thereto.

First, the hard mask layer (m1) is formed on the support 10 using the hard-mask forming composition according to the first aspect stated above (FIGS. 1 and 2; step (iii-i)). The present step is the same as step (ii-i) stated above.

Subsequently, the inorganic pattern (m2p) made of an inorganic material is formed on the hard mask layer (m1) (FIG. 6; step (iii-v)). Examples of the inorganic material for forming the inorganic pattern (m2p) include the same inorganic material as exemplified in step (ii-ii), a resist composition containing the inorganic material, and the like. A method for forming the inorganic pattern (m2p) is not particularly limited, and known methods in the related art can be used. For example, the inorganic resist film is formed on the hard mask layer (m1) using a resist composition containing an inorganic material, and exposed and developed, thereby forming an inorganic pattern (m2p) on the hard mask layer (m1).

Subsequently, the hard mask layer (m1) is etched using the inorganic pattern (m2p) as a mask to form the resin pattern (m1p) (FIG. 7; step (iii-vi)). The present step is the same as the above step (ii-vi).

Subsequently, the support 10 is processed using the resin pattern (m1p) as a mask to form a pattern 12p (FIG. 8; step (iii-vii)). The present step is the same as step (ii-vii) stated above.

The electronic component 100 provided with the pattern 12p on the substrate 11 can also be manufactured in this manner.

In the method for manufacturing an electronic component of each of the embodiments described above, the hard mask layer (m1) is formed using the hard-mask forming composition according to the first aspect stated above, and thus it is possible to manufacture an electronic component excellent in etching resistance, crack resistance, and low outgassing property with high quality and stability.

The present invention is not limited to each of the embodiments described above, various modifications can be made within the scope shown in claims, and embodiments obtained by suitably combining technical means disclosed in different embodiments are also included in the technical scope of the present invention.

### EXAMPLES

Hereinafter, the present invention will be described in more detail referring to examples. However, the present invention is not limited to these examples.

<Production Example of Resin (P1)>

<<Resin (P1-1)>>

In a three-necked flask connected to a thermometer, a reflux tube and a nitrogen inlet tube, 9.28 g (59.81 mmol) of 1-naphthaldehyde, 10.00 g (59.81 mmol) of carbazole, and 26.62 g of γ-butyrolactone (GBL) were dissolved, 2.87 g of 20% GBL solution of methanesulfonic acid was added to the resultant mixture, and the mixture was heated and stirred at the reaction temperature of 120° C. for 8 hours. After that, the reaction solution was cooled to room temperature.

The obtained reaction solution was dropwise added to 150 g of a 9/1 mixed solution of methanol (MeOH)/5% ammonia water to precipitate a polymer, and the precipitated brown powder was washed twice with 150 g of MeOH to obtain a target resin (P1-1) by drying under reduced pressure.

For the resin (P1-1), a weight average molecular weight (Mw) of standard polystyrene conversion calculated by GPC measurement was 4,500, and the polydispersity (Mw/Mn) was 2.07.

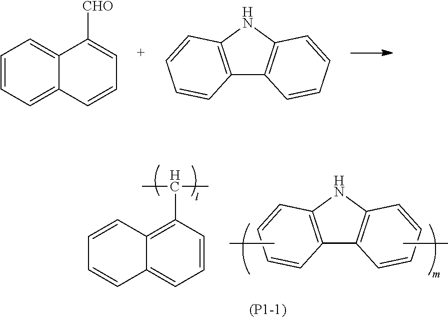

<<Resin (P1-2) to (P1-8)>>

Resins (P1-2) to (P1-8) having composition ratios shown in Table 1 were produced in the same manner as in the production example of <<Resin (P1-1)>> except that the monomer was changed.

For the obtained resin, the copolymerization composition ratio (proportion (molar ratio) of each structural unit of the resin) of the resin calculated from the charged amount, and a weight average molecular weight (Mw) of standard polystyrene conversion calculated by GPC measurement and the polydispersity (Mw/Mn) were also shown in Table 1.

The produced resins (P1-1) to (P1-8) are shown below.

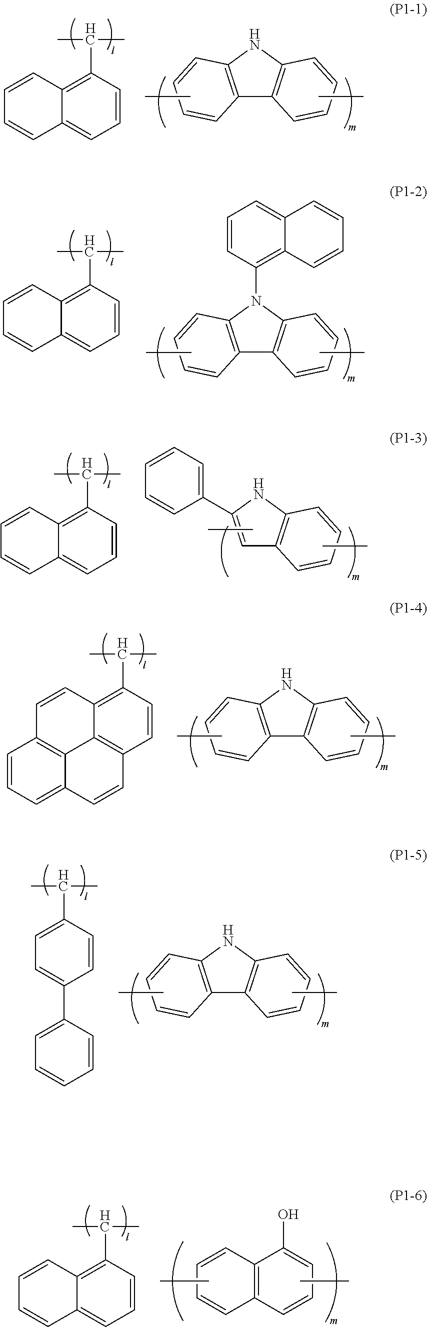

TABLE 1

| | | | Weight average | |
|---|---|---|---|---|
| | | Copolymerization | molecular | Polydis- |
| | | composition ratio | weight | persity |
| | Resin | (molar ratio) of resin | (Mw) | (Mw/Mn) |
| Production | (P1-1) | l/m = 50/50 | 4500 | 2.07 |
| Example 1 | | | | |
| Production | (P1-2) | l/m = 50/50 | 1500 | 1.30 |
| Example 2 | | | | |
| Production | (P1-3) | l/m = 50/50 | 6500 | 2.59 |
| Example 3 | | | | |
| Production | (P1-4) | l/m = 50/50 | 2400 | 1.66 |
| Example 4 | | | | |
| Production | (P1-5) | l/m = 50/50 | 8800 | 2.84 |
| Example 5 | | | | |
| Production | (P1-6) | l/m = 50/50 | 2800 | 1.72 |
| Example 6 | | | | |
| Production | (P1-7) | l/m = 50/50 | 2300 | 1.65 |
| Example 7 | | | | |
| Production | (P1-8) | l/m = 50/50 | 2200 | 1.61 |
| Example 8 | | | | |

### Examples 1 to 15 and Comparative Examples 1 to 6

<Preparation of Hard-Mask Forming Composition>

Components listed in Tables 2 and 3 were mixed together and dissolved to prepare hard-mask forming compositions of each example.

TABLE 2

| | | | | Thermal | | | |
|---|---|---|---|---|---|---|---|
| | Resin | Compound | Phenol | acid | | | |
| | component | (C1) | compound | generator | Surfactant | Solvent | |
| Example 1 | (P1)-1 | (C1)-1 | — | (T)-1 | (A)-1 | (S)-1 | (S)-2 |
| | [100] | [20] | | [2.0] | [0.10] | [100] | [330] |
| Example 2 | (P1)-2 | (C1)-1 | — | (T)-1 | (A)-1 | (S)-1 | (S)-2 |
| | [100] | [20] | | [2.0] | [0.10] | [100] | [330] |
| Example 3 | (P1)-3 | (C1)-1 | — | (T)-1 | (A)-1 | (S)-1 | (S)-2 |
| | [100] | [20] | | [2.0] | [0.10] | [100] | [330] |
| Example 4 | (P1)-3 | (C1)-2 | — | (T)-1 | (A)-1 | (S)-1 | (S)-2 |
| | [100] | [20] | | [2.0] | [0.10] | [100] | [330] |
| Example 5 | (P1)-4 | (C1)-1 | — | (T)-1 | (A)-1 | (S)-1 | (S)-2 |
| | [100] | [20] | | [2.0] | [0.10] | [100] | [330] |
| Example 6 | (P1)-4 | (C1)-2 | — | (T)-1 | (A)-1 | (S)-1 | (S)-2 |
| | [100] | [20] | | [2.0] | [0.10] | [100] | [330] |
| Example 7 | (P1)-5 | (C1)-1 | — | (T)-1 | (A)-1 | (S)-2 | (S)-3 |
| | [100] | [20] | | [2.0] | [0.10] | [247.5] | [82.5] |
| Example 8 | (P1)-4 | (C1)-1 | (ph)-1 | (T)-1 | (A)-1 | (S)-1 | (S)-2 |
| | [100] | [20] | [30] | [2.0] | [0.10] | [100] | [200] |
| Example 9 | (P1)-4 | (C1)-1 | (ph)-2 | (T)-1 | (A)-1 | (S)-1 | (S)-2 |
| | [100] | [15] | [60] | [2.0] | [0.10] | [100] | [200] |
| Example 10 | (P1)-6 | (C1)-1 | — | (T)-1 | (A)-1 | (S)-1 | (S)-2 |
| | [100] | [20] | | [2.0] | [0.10] | [100] | [330] |
| Example 11 | (P1)-7 | (C1)-1 | — | (T)-1 | (A)-1 | (S)-1 | (S)-2 |
| | [100] | [20] | | [2.0] | [0.10] | [100] | [330] |
| Example 12 | (P1)-8 | (C1)-1 | — | (T)-1 | (A)-1 | (S)-1 | (S)-2 |
| | [100] | [20] | | [2.0] | [0.10] | [100] | [330] |

TABLE 3

| | | | | | Thermal | | | |
|---|---|---|---|---|---|---|---|---|
| | Resin | Compound | Crosslinking | Phenol | acid | | | |
| | component | (C1) | agent | compound | generator | Surfactant | Solvent | |
| Comparative | (P2)-1 | (C1)-1 | — | — | (T)-1 | (A)-1 | (S)-1 | (S)-2 |
| Example 1 | [100] | [20] | | | [2.0] | [0.10] | [100] | [330] |
| Comparative | (P1)-1 | — | (X)-1 | (ph)-2 | (T)-1 | (A)-1 | (S)-1 | (S)-2 |
| Example 2 | [100] | | [30] | [60] | [2.0] | [0.10] | [100] | [330] |
| Comparative | (P1)-1 | — | (X)-2 | — | (T)-1 | (A)-1 | (S)-1 | (S)-2 |
| Example 3 | [100] | | [30] | | [2.0] | [0.10] | [100] | [330] |
| Comparative | — | (C1)-1 | — | (ph)-1 | (T)-1 | (A)-1 | (S)-1 | (S)-2 |
| Example 4 | | [20] | | [100] | [2.0] | [0.10] | [100] | [330] |
| Comparative | (P1)-6 | — | (X)-1 | — | (T)-1 | (A)-1 | (S)-1 | (S)-2 |
| Example 5 | [100] | | [20] | | [2.0] | [0.10] | [100] | [330] |
| Comparative | (P1)-1 | — | (X)-3 | — | (T)-1 | (A)-1 | (S)-1 | (S)-2 |
| Example 6 | [100] | | [20] | | [2.0] | [0.10] | [100] | [330] |

Each abbreviation in Tables 2 and 3 is defined as follows. The numerical values in [ ] are blending amounts (parts by mass).

(P1)-1 to (P1)-8: The resins (P1-1) to (P1-8)

(P2)-1: A resin (P2-1) represented by the following chemical formula (P2-1) The weight average molecular weight (Mw) of the standard polystyrene conversion obtained by GPC measurement was 15,000, and the polydispersity (Mw/Mn) was 24.4.

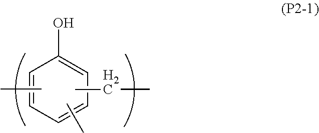

(C1)-1: A compound represented by the following chemical formula (C1-1)

(C1)-2: A compound represented by the following chemical formula (C1-2)

(X)-1: A compound represented by the following chemical formula (X-1)

(X)-2: A compound represented by the following chemical formula (X-2)

(X)-3: A compound represented by the following chemical formula (X-3)

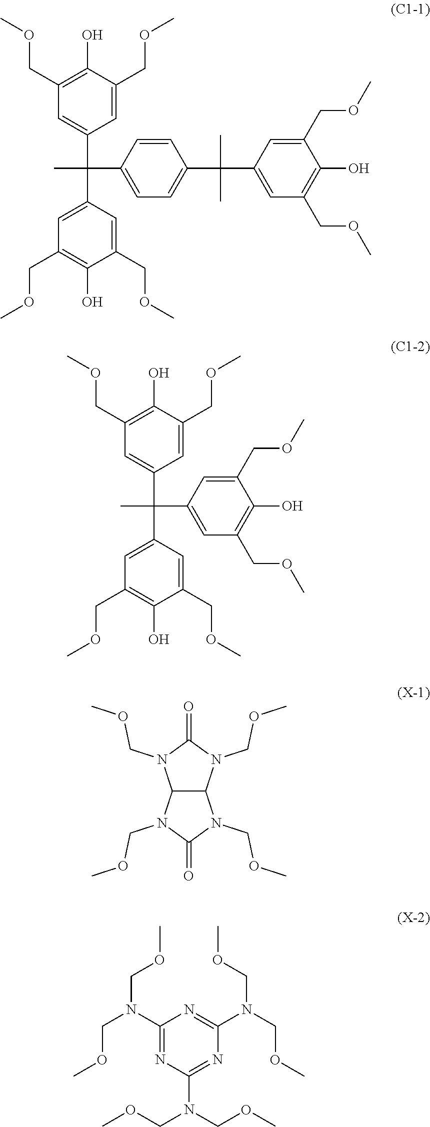

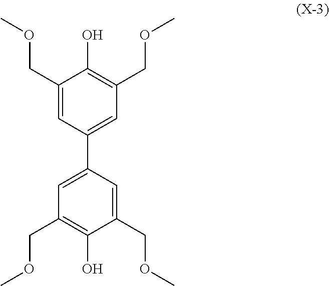

(ph)-1: A compound represented by the following chemical formula (ph-1)

(ph)-2: A compound represented by the following chemical formula (ph-2)

(T)-1: A compound represented by the following chemical formula (T-1)

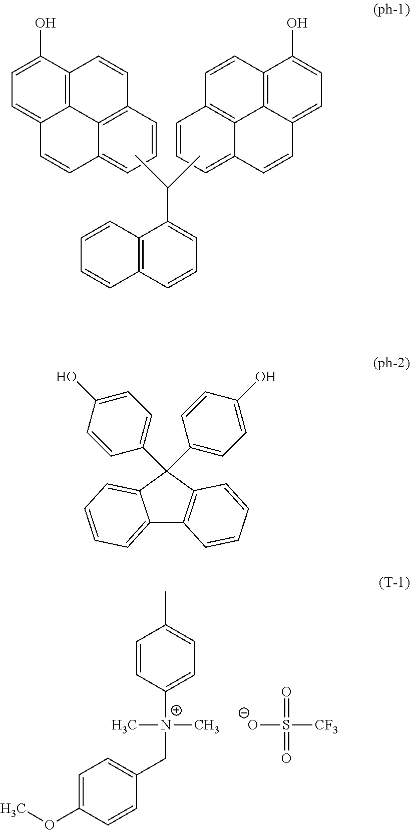

(A)-1: Fluorinated surfactant, product name “R-40” manufactured by DIC Corporation

(S)-1: γ-butyrolactone

(S)-2: Propylene glycol monomethyl ether

(S)-3: Cyclohexanone

<Formation of Hard Mask Layer>

Each of the hard-mask forming compositions of each examples was coated on a silicon wafer using a spinner. Thereafter, baking was performed at a temperature of 400° C. for 90 seconds to form a hard mask layer having a thickness of 1.0 μm (2.0 μm for Examples 8 and 9). In Examples 8 and 9, the thickness of the hard mask layer was set to 2.0 μm in order to evaluate under more severe conditions (prone to cracking).

<Evaluation>

The hard mask layers of each example were evaluated for etching resistance, crack resistance, and low outgassing properties by the methods shown below. These results are shown in Tables 4 and 5 as “etching”, “crack”, and “outgas”.

[Evaluation of Etching Resistance]

The hard mask layer of each example formed by the above <formation of hard mask layer> was subjected to dry etching, and the amount of film loss was measured to obtain an etching rate ratio.

The measurement conditions for the amount of film loss due to the dry etching were set as follows.
Processing time: 3 minutes processing with TCP type dry etching apparatus Gas: CF₄/N₂ (80/20)

The etching rate ratio was calculated as a proportion of the amount of film loss of the hard mask layer of each example to the amount of film loss of the hard mask layer made of the resin (P2-1) stated above, which is a general cresol novolac resin (etching rate ratio=(amount of film loss of the hard mask layer of each example)/(amount of film loss of the hard mask layer made of resin (P2-1))×100).

This means the lower this value, the higher the etching resistance.

The obtained values were evaluated according to the following criteria.

A: Etching rate ratio is less than 65%

B: Etching rate ratio is 65% or more and less than 80%

C: Etching rate ratio is 80% or more

[Evaluation of Crack Resistance]

For the hard mask layer of each example formed of the above-stated <formation of hard mask layer>, the hard mask layer of each example was observed with an OptoDigital Microscope DSX500, and the occurrence of cracks was evaluated according to the following criteria.

Evaluation Criteria

A: No cracks were observed in the hard mask layer

B: About 10 cracks were observed in the hard mask layer

C: Many cracks were observed in the hard mask layer

[Evaluation of Low Outgassing Property]

For the hard mask layer of each example formed of the above-stated <formation of hard mask layer>, using a thermogravimetric differential thermal analyzer (TG-DTA), the temperature was raised to 240° C. to 400° C. at a temperature rising rate of 10° C./min It was measured how much the weight of the hard mask layer decreased when heated at 400° C. as compared with when heated at 240° C., and occurrence of the outgas of the hard mask layer was evaluated according to the following criteria.

Evaluation Criteria

A: Weight reduction rate is 5% or less

B: Weight reduction rate is more than 5% and equal to or less than 10%

C: Weight reduction rate exceeds 10%

TABLE 4

| | Etching | Crack | Outgas |
|---|---|---|---|
| Example 1 | B | A | B |
| Example 2 | A | B | B |
| Example 3 | A | A | B |
| Example 4 | A | A | B |
| Example 5 | A | B | A |
| Example 6 | A | B | A |
| Example 7 | B | B | B |
| Example 8 | A | A | A |
| Example 9 | A | A | A |
| Example 10 | B | A | B |
| Example 11 | B | A | B |
| Example 12 | A | B | B |

TABLE 5

| | Etching | Crack | Outgas |
|---|---|---|---|
| Comparative Example 1 | C | A | C |
| Comparative Example 2 | B | C | C |
| Comparative Example 3 | B | C | C |
| Comparative Example 4 | C | B | C |
| Comparative Example 5 | B | B | C |
| Comparative Example 6 | B | C | C |

As shown in Tables 4 and 5, it was confirmed that the hard mask layer formed of the hard-mask forming composition of the example was excellent in etching resistance, crack resistance and low outgassing property.

In addition, when the hard-mask forming composition of Example 3 and the hard-mask forming composition of Example 4 were compared with each other, the hard mask layer formed of the hard-mask forming composition of Example 3 containing a compound represented by the chemical formula (C1-1), as the compound (C1), was excellent in all of etching resistance, crack resistance, and low outgassing property.

In addition, when the hard-mask forming composition of Example 5 and the hard-mask forming composition of Example 6 was compared with each other, the hard mask layer formed of the hard-mask forming composition of Example 5 containing a compound represented by the chemical formula (C1-1), as the compound (C1), was excellent etching resistance, crack resistance, and low outgassing property.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A hard-mask forming composition comprising:
a resin (P1) containing a structural unit (u11) represented by General Formula (u1-1) or a structural unit (u12) represented by General Formula (u1-2) and a structural unit (u2) having an aromatic ring and a polar group; and
a compound (C1) represented by General Formula (c-1): 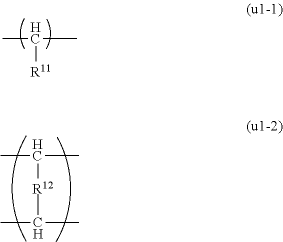
wherein R¹¹ is an aromatic hydrocarbon group which may have a substituent, and R¹² is an aromatic hydrocarbon group which may have a substituent; and 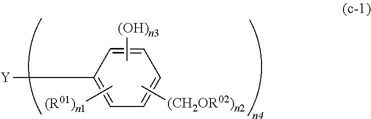
wherein Y is an organic group, R⁰¹ is a hydrocarbon group having 1 to 40 carbon atoms, R⁰² is an alkyl group having 1 to 10 carbon atoms which may have an alkoxy group having 1 to 10 carbon atoms, n1 is an integer of 0 to 3, n2 is an integer of 1 to 4, n3 is an integer of 1 to 3, n1 to n3 satisfy 2≤n1+n2+n3≤5, n4 is an integer of 3 or more, and a plurality of R⁰¹'s, R⁰²'s, n1's, n2's, and n3's may be the same as or different from each other, respectively, provided that the number of —CH₂OR⁰² in the formula is 6 or more as a whole of the compound (C1).

2. The hard-mask forming composition according to claim 1, wherein the structural unit (u2) is a structural unit (u21) represented by General Formula (u2-1), a structural unit (u22) represented by General Formula (u2-2), or a structural unit (u23) represented by General Formula (u2-3): 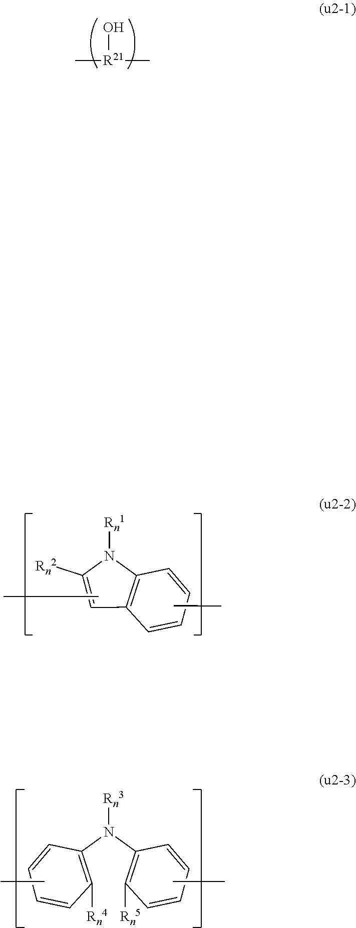
wherein R²¹ is an aromatic hydrocarbon group which may have a substituent, Rn¹ and Rn² are each independently a hydrogen atom or a hydrocarbon group, Rn³ to Rn⁵ are each independently a hydrogen atom or a hydrocarbon group, and Rn⁴ and Rn⁵ may be bonded to each other to form a condensed ring with a nitrogen atom in the formula.

3. The hard-mask forming composition according to claim 1, further comprising a phenol compound.

4. The hard-mask forming composition according to claim 1, wherein a content of the compound (C1) is 10 to 30 parts by mass with respect to 100 parts by mass of the resin (P1).

5. The hard-mask forming composition according to claim 1, further comprising a thermal acid generator component.

6. A method for manufacturing an electronic component, comprising:
forming a hard mask layer (m1) on a support using the hard-mask forming composition according to claim 1; and
processing the support using the hard mask layer (m1) as a mask.

7. A method for manufacturing an electronic component, comprising:
forming a hard mask layer (m1) on a support using the hard-mask forming composition according to claim 1;
forming a hard mask layer (m2) made of an inorganic material on the hard mask layer (m1);
forming a resist film on the hard mask layer (m2);
exposing the resist film and developing the exposed resist film to form a resist pattern on the hard mask layer (m2);
etching the hard mask layer (m2) using the resist pattern as a mask to form an inorganic pattern;
etching the hard mask layer (m1) using the inorganic pattern as a mask to form a resin pattern; and
processing the support using the resin pattern as a mask.

8. A method for manufacturing an electronic component, comprising:
forming a hard mask layer (m1) on a support using the hard-mask forming composition according to claim 1;
forming an inorganic pattern made of an inorganic material on the hard mask layer (m1);
etching the hard mask layer (m1) using the inorganic pattern as a mask to form a resin pattern; and
processing the support using the resin pattern as a mask.
